(19) United States
(12) Patent Application Publication
(10) Pub. No.: US 2024/0120964 A1
(43) Pub. Date: Apr. 11, 2024

(54) PACKAGED INTEGRATED CIRCUIT HAVING PACKAGE SUBSTRATE WITH INTEGRATED ISOLATION CIRCUIT

(71) Applicant: TEXAS INSTRUMENTS INCORPORATED, Dallas, TX (US)

(72) Inventors: Giacomo Calabrese, Freising (DE); Nicola Bertoni, Freising (DE); Misha Ivanov, Freising (DE)

(21) Appl. No.: 18/542,381

(22) Filed: Dec. 15, 2023

Related U.S. Application Data
(63) Continuation-in-part of application No. 18/347,201, filed on Jul. 5, 2023.
Application No. 18/347,201 is a division of application No. 17/167,753, filed on Feb. 4, 2021, now Pat. No. 11,716,117.
(60) Provisional application No. 63/131,407, filed on Dec. 29, 2020.
(60) Provisional application No. 62/976,427, filed on Feb. 14, 2020.

(51) Int. Cl. H05K 1/16; H05K 3/46

(52) U.S. Cl. CPC H04B 5/75; H04B 5/266; H05K 1/162; H05K 1/165; H05K 3/4673

(57) ABSTRACT

A package substrate includes a first metal layer, a second metal layer, isolation material containing the first and second metal layers, an isolation circuit, a first plurality of contact pads, and a second plurality of contact pads. The isolation circuit includes a first circuit element in the first metal layer and a second circuit element in the second metal layer and electrically isolated from the first circuit element by the isolation material. The first plurality of contact pads is adapted to be coupled to a first integrated circuit on the package substrate and includes a first contact pad coupled to the first circuit element. The second plurality of contact pads is adapted to be coupled to a second integrated circuit on the package substrate and includes a second contact pad coupled to the second circuit element.

### CROSS REFERENCE TO RELATED APPLICATIONS

This application is a Continuation-in-Part of U.S. patent application Ser. No. 18/347,201, titled, “CIRCUIT SUPPORT STRUCTURE WITH INTEGRATED ISOLATION CIRCUITRY,” filed Jul. 5, 2023, which is a Divisional application of and claims the benefit of priority to, U.S. patent application Ser. No. 17/167,753, titled “CIRCUIT SUPPORT STRUCTURE WITH INTEGRATED ISOLATION CIRCUIT,” filed Feb. 4, 2021, which claims priority to U.S. Provisional Patent Application No. 62/976,427 filed Feb. 14, 2020, and U.S. Provisional Patent Application No. 63/131,407 filed Dec. 29, 2020, all which are incorporated herein by reference.

### BACKGROUND

Isolation is often desirable for interconnecting electrical systems to exchange data or power between the systems. For example, two systems may be powered by different supply sources that do not share a common ground connection. The two systems may be electrically isolated to prevent current and voltages in one system from negatively impacting the other system, for instance by damaging or interfering with the operation of one or more components of the other system. Transformer and capacitor isolation are two approaches that are used. Transformer isolation may be used to exchange power between two systems, and capacitor-based isolation may be used to exchange power or data between the two systems. In some applications that use isolation circuits, challenges may arise with respect to maintaining voltage isolation, interconnection parasitics, and isolation circuit efficiency.

### SUMMARY

Described examples include package substrates and an integrated circuit package having an integrated isolation circuit (e.g., circuit support structure). Described examples also include a method for making a circuit support structure having an integrated isolation circuit. Integrating or embedding the isolation circuit into the circuit support structure allows for a smaller integrated circuit package while maintaining voltage isolation. Moreover, additional benefits such as improved efficiency of the integrated isolation circuit, reduced interconnection parasitics, and improved thermal performance may be realized when implementing one or more examples as described herein.

In one example, a circuit support structure includes a first metal layer, a second metal layer, isolation material containing the first and second metal layers, an isolation circuit, a first plurality of contact pads, and a second plurality of contact pads. The isolation circuit includes a first circuit element in the first metal layer and a second circuit element in the second metal layer and electrically isolated from the first circuit element by the isolation material. The first plurality of contact pads is adapted to be coupled to a first integrated circuit on the circuit support structure and includes a first contact pad coupled to the first circuit element. The second plurality of contact pads is adapted to be coupled to a second integrated circuit on the circuit support structure and includes a second contact pad coupled to the second circuit element.

In another example, a circuit support structure includes a first metal layer, a second metal layer, mold compound containing the first and second metal layers and defining a mounting surface of the circuit support structure, an isolation circuit, a first plurality of contact pads, and a second plurality of contact pads. The isolation circuit includes a first circuit element in the first metal layer and a second circuit element in the second metal layer and electrically isolated from the first circuit element by the mold compound. The first plurality of contact pads is exposed at the mounting surface and includes a first contact pad coupled to the first circuit element. The second plurality of contact pads is exposed at the mounting surface and includes a second contact pad coupled to the second circuit element.

In another example, an integrated circuit package includes a circuit support structure, a first integrated circuit, and a second integrated circuit. The circuit support structure includes a first metal layer, a second metal layer, isolation material containing the first and second metal layers, an isolation circuit, a first plurality of contact pads, and a second plurality of contact pads. The isolation circuit includes a first circuit element in the first metal layer and a second circuit element in the second metal layer and electrically isolated from the first circuit element by the isolation material. The first plurality of contact pads includes a first contact pad coupled to the first circuit element. The second plurality of contact pads includes a second contact pad coupled to the second circuit element. The first integrated circuit is on the circuit support structure and coupled to the first plurality of contact pads, and the second integrated circuit is on the circuit support structure and coupled to the second plurality of contact pads.

In another example, a method of making a circuit support structure having an integrated isolation circuit includes forming, in metal layers, first and second circuit elements of isolation circuit, a first plurality of contact pads including a first contact pad, a second plurality of contact pads including a second contact pad, and a third plurality of contact pads. The method also includes coupling the first contact pad to the first circuit element, coupling the second contact pad to the second circuit element, and coupling some of the first plurality of contact pads and some of the second plurality of contact pads to the third plurality of contact pads. The method also includes encapsulating the metal layers in isolation material such that the first and second circuit elements are electrically isolated from each other, the first plurality of contact pads and the second plurality of contact pads are exposed at a first surface defined by the isolation material, and the third plurality of contact pads is exposed at a second opposing surface defined by the isolation material.

In another example, a packaged integrated circuit comprises a package substrate including an isolation circuit, the isolation circuit including a first primary side terminal, a second primary side terminal, a first secondary side terminal, and a second secondary side terminal. In at least one example, a first semiconductor die is on the package substrate and coupled to the first primary side terminal and the second primary side terminal. In at least one example, a second semiconductor die is on the package substrate and coupled to the first secondary side terminal and the second secondary side terminal.

In another example, a packaged integrated circuit comprises a package substrate including a first transformer including a first primary winding and a first secondary winding, the first primary winding coupled between a first primary side terminal and a second primary side terminal, and the first secondary winding coupled between a first secondary side terminal and a second secondary side terminal. In at least one example, the package substrate includes a second transformer including a second primary winding and a second secondary winding, the second primary winding coupled between a third primary side terminal and a fourth primary side terminal, and the second secondary winding coupled between a third secondary side terminal and a fourth secondary side terminal. In at least one example, the packaged integrated circuit includes a first semiconductor die on the package substrate and coupled to the first primary side terminal and the second primary side terminal. In at least one example, the packaged integrated circuit includes a second semiconductor die on the package substrate and coupled to the first secondary side terminal and the second secondary side terminal.

In at least one example, a method comprises coupling a first primary winding of a first transformer between a first primary side terminal and a second primary side terminal. The method further comprises coupling a first secondary winding of the first transformer between a first secondary side terminal and a second secondary side terminal. The method further comprises coupling a second primary winding of a second transformer between a third primary side terminal and a fourth primary side terminal. The method further comprises coupling a second secondary winding of the second transformer between a third secondary side terminal and a fourth secondary side terminal, wherein the first transformer and the second transformer are in a package substrate. The method further comprises coupling the first primary side terminal and the second primary side terminal to a first semiconductor die on the package substrate. The method further comprises coupling the first secondary side terminal and the second secondary side terminal to a second semiconductor die on the package substrate.

### BRIEF DESCRIPTION OF THE DRAWINGS

The examples will be understood more fully from the detailed description given below and from the accompanying drawings, which, however, should not be taken to limit the disclosure to the specific examples, but are for explanation and understanding only.

FIG. 1 is a schematic depicting an example packaged integrated circuit (IC) having an integrated isolation circuit, in accordance with at least one example.

FIG. 2A is a schematic depicting another example packaged IC having an integrated isolation circuit including inductive and capacitive isolation channels coupled to first and second semiconductor dies, in accordance with at least one example.

FIG. 2B is a schematic illustrating a packaged IC having an integrated isolation circuit including inductive isolation channels coupled to the first and second semiconductor dies, in accordance with at least one example.

FIG. 2C is a schematic illustrating a packaged IC having a third semiconductor die coupled to the second semiconductor die, in accordance with at least one example.

FIG. 2D is a schematic illustrating a packaged IC having a third semiconductor die coupled to the second semiconductor die, and where data circuits are separate semiconductor dies, in accordance with at least one example.

FIG. 3 is schematic showing an isometric view of an example packaged IC having an integrated isolation circuit including an inductive channel coupled within the packaged IC without the use of wire bonding, in accordance with at least one example.

FIG. 4 is a schematic showing a top-down plan view of the example packaged IC shown in FIG. 3, in accordance with at least one example.

FIG. 5 is a schematic showing a side view of the example packaged IC shown in FIG. 3, in accordance with at least one example.

FIG. 6 is a schematic showing an isometric view of another example packaged IC having an integrated isolation circuit including an inductive channel coupled within the packaged IC using wire bonding, in accordance with at least one example.

FIG. 7 is a schematic showing a top-down plan view of the example packaged IC shown in FIG. 6, in accordance with at least one example.

FIG. 8 is a schematic showing a side view of the example packaged IC shown in FIG. 6, in accordance with at least one example.

FIG. 9 is a schematic showing a top-down plan view depicting another example packaged IC having an integrated isolation circuit including an inductive channel coupled within the packaged IC without the use of wire bonding, in accordance with at least one example.

FIG. 10 is a schematic showing a partial cross-sectional view taken from the example packaged IC shown in FIG. 9, in accordance with at least one example.

FIG. 11 is a schematic showing an isometric view of another example packaged IC having an integrated isolation circuit including inductive and capacitive isolation channels, in accordance with at least one example.

FIG. 12 is a flowchart of an example method for making a package substrate having an integrated isolation circuit, in accordance with at least one example.

FIGS. 13A-B are schematics showing a circuit model of a capacitive isolation circuit coupled to a differential transmitter and a differential receiver, and an equivalent circuit model for the common mode applied across the isolation barrier, respectively, in accordance with some examples.

FIGS. 13C-D are schematics showing a circuit model of an inductive isolation circuit coupled to the differential transmitter and the differential receiver, and an equivalent circuit model for the common mode applied across the isolation barrier, respectively, in accordance with some examples.

FIG. 13E is a plot showing common mode gain as a function of frequency at the differential receiver coupled to the capacitive isolation circuit and the inductive isolation circuit, in accordance with at least one example.

FIG. 14 is a schematic of data circuits and their respective inductive isolation circuits, in accordance with at least one example.

FIG. 15 is a schematic showing a top view of a packaged IC with separate power and data semiconductor dies, three transformers, and an application specific semiconductor die, in accordance with at least one example.

FIG. 16 is a schematic showing an isometric top view of another example data transformers under the data semiconductor dies, in accordance with at least one example.

FIG. 17 is a schematic showing an isometric bottom view of the three transformers of FIG. 15, in accordance with at least one example.

FIG. 18 is a schematic showing an isometric top view of the packaged integrated circuit where data transformers are enclosed by the power transformers, in accordance with at least one example.

FIG. 19 is a schematic showing a cross-sectional view of a packaged IC having a package substrate with three metal layers, in accordance with at least one example.

FIG. 20 is a schematic showing an isometric top view of a packaged IC with partially overlapping primary and secondary windings of the data transformers, in accordance with at least one example.

FIG. 21 is a schematic showing a top zoomed-in view of the packaged IC of FIG. 20 with the partially overlapping primary and secondary windings of the data transformers, in accordance with at least one example.

FIG. 22 is a schematic showing an isometric top zoomed-in view of the partially overlapping primary and secondary windings of the data transformers, in accordance with at least one example.

FIG. 23 is a schematic showing an isometric top zoomed-in view of the partially overlapping primary and secondary windings of the data transformers, in accordance with at least one example.

FIG. 24 is a flowchart of a method of forming the packaged IC with three transformers, in accordance with at least one example.

### DETAILED DESCRIPTION OF EXAMPLE EMBODIMENTS

Described herein is a packaged integrated circuit (IC) that comprises two or more semiconductor dies that are coupled to an isolation circuit (e.g., an isolation barrier) which is integrated within a package substrate. In at least one example, the package substrate includes three metal layers. In at least one example, the package substrate includes two metal layers. In at least one example, the two or more semiconductor dies include a first semiconductor die with a first power IC and a second semiconductor die with a second power IC, where the first semiconductor die is coupled to the second semiconductor die via a power transformer which is part of the isolation circuit. In at least one example, the first semiconductor die and the second semiconductor die include data circuits that are coupled via a second set of transformers (e.g., data transformers), which are also part of the isolation circuit. The data circuits provide bidirectional signaling, in accordance with at least one example. In at least one example, the data circuits may be separate semiconductor dies on the package substrate. In at least one example, the second set of transformers are enclosed by, or otherwise positioned within a footprint of, the power transformers. In at least one example, the second set of transformers are positioned outside the footprint of the power transformers. In at least one example, semiconductor dies are flip-chip dies that allow connection with the transformer(s) below it with reduced interconnection.

In at least one example, the data circuits are used for sending and receiving signals between the first and second power semiconductor dies to realize a DC-DC converter. In at least one example, the data circuits can be used for other functions such as telemetry, data signaling, buffering of analog input signals for an analog-to-digital converter, buffering of digital input signals for a digital-to-analog converter, etc. In at least one example, an additional semiconductor die is positioned on the packaged substrate, where the additional semiconductor die receives power from the second power semiconductor die and exchanges data with the data circuit. The additional semiconductor die can be any application specific semiconductor die or a general microcontroller.

By integrating the semiconductor dies for power regulation and data transfer with the isolation circuit, which is integrated in the package substrate, overall size of the packaged IC is reduced. The flip-chip assembly for the semiconductor dies allows for tighter parameter control which reduces the size or area of the packaged IC, which allows for shorter and/or fewer interconnect routing, closer connections, smaller parasitic capacitances, resistances, and/or inductances, etc. One or more flip-chip dies overlap the transformers below the flip-chip dies and this configuration reduces parasitic capacitances, resistances, and/or inductances involved in connecting the transformers to the flip-chip dies. Routing over the package substrate is reduced as most signal and power routings can be in the package substrate. The reduced parasitic capacitances, resistances, and/or inductances involved in connecting the transformers of the isolation circuit with respect to a bonded assembly, allow tailoring of the power and data channels down to the application needs and achieve higher power transfer efficiency.

Moreover, by placing the transformers of the isolation circuit in the package substrate, which can be much thicker than the transformer windings, the vertical separation between the transformer windings and the semiconductor die can be increased, at least compared with the case where the transformer windings (or other isolation circuit) formed in the metallization layer over the semiconductor die. Such arrangements can reduce the parasitic capacitance between the transformer windings and the semiconductor die, which can provide connection to ground. The reduced parasitic capacitance can improve the quality factor (Q) of the transformer. The increased vertical separation can also reduce the eddy current in the semiconductor die caused by the magnetic field generated by the transformer, which can reduce loss and further improve power or signal transfer efficiency. Further, as to be explained below, the transformer can also provide improved common mode transient immunity and improved matching for differential signals.

The flexibility in the routing capability of the package substrate also improves the connectivity and signal integrity of the serviced application specific IC. The packaged IC of some examples integrate power and bidirectional data communication with minimized crosstalk, so that they operate independently, which makes the use of the isolated co-packaged device more flexible. In at least one example, the package substrate with three metal layers improves efficiency for power transformers using thicker metal (e.g., copper) traces. Since the semiconductor dies are over the package substrate, the transformers in the package substrate produce higher QFs since the windings of the transformers are not in lateral proximity to the semiconductor dies. Embedding the data transformers in the substrate allows for high frequency signal communication between data integrated circuits. Routing signal and power through a package substrate having three metal layers reduces interconnect congestion on top of the substrate, which allows for smaller packaged integrated circuit as semiconductor dies in the packaged integrated circuit are placed closer to one another. In at least one example, the transformers are arranged within a two-layer substrate, which further reduces fabrication cost, vertical size, and cost of the packaged IC. Flexible routing in the package substrate allows for better control over near field interaction and coupling between the transformers and the application specific integrated circuit.

In the drawings, like reference numerals refer to like elements throughout, and the various features are not necessarily drawn to scale. Here, the same reference numbers or other reference designators are used in the drawings to designate the same or similar (either by function and/or structure) features.

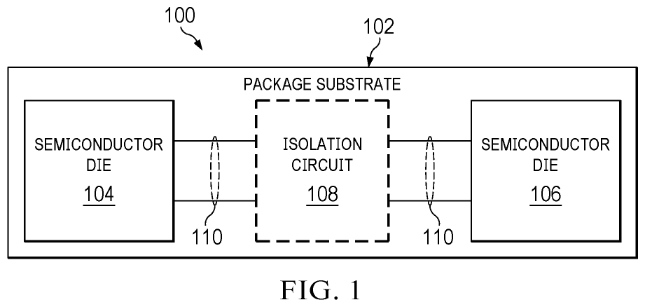

Referring initially to FIG. 1, which is a block diagram depicting an example packaged IC 100 having an integrated isolation circuit 108. In at least one example, packaged IC 100 includes a package substrate 102, a semiconductor die 104, and a semiconductor die 106. Semiconductor dies 104 and 106 are mounted to package substrate 102, which can support semiconductor dies 104 and 106 as a circuit support structure. As used herein, an IC is circuit built on a semiconductor substrate, such as a silicon wafer. A package substrate, such as a lead frame, is a structure that is configured to allow the mounting thereon of an IC and is configured to provide electrical interconnectivity between the IC and one or more circuits external to the package substrate.

In accordance with at least one example of this description, isolation circuit 108 is integrated, formed, or embedded into layers (not shown) of package substrate 102, as indicated by dashed lines. Moreover, in further accordance with at least one example of this description, package substrate 102 includes contact pads (not shown) and may include metallic interconnects 110 (four shown) to allow interconnectivity between semiconductor dies 104 and 106 and isolation circuit 108. Each interconnect 110 may represent one or more electrical traces and/or vias.

In at least one example, isolation circuit 108 (and other isolation circuit examples in accordance with this description) may provide a galvanic isolation barrier between two different power domains. In at least one example, packaged IC 100 represents a direct current (DC)-to-DC converter having a transformer as isolation circuit 108. Accordingly, semiconductor die 104 may include circuit, such as a half-bridge circuit or a full-bridge circuit and a driver circuit, for providing a voltage and a current from other circuit to a primary winding of the transformer. In an example, the voltage and the current are provided from a power supply for a printed circuit board (PCB) on which package substrate 102 is mounted. The PCB may be used to power a device such as a motor or a computing device. Semiconductor die 106 may include a bridge circuit and a driver and regulation circuit for receiving a voltage and a current from a secondary winding of the transformer and providing one or more regulated output voltages and/or currents for use by a load on the PCB. The load may be an application-specific integrated circuit (ASIC), a field-programmable gate array (FPGA), a microcontroller, a processor, etc. In other examples, semiconductor dies 104 and/or 106 may represent controller circuit, current and voltage sensors, gate drivers for insulated-gate bipolar transistors, gate drivers for field effect transistors (FETs), etc.

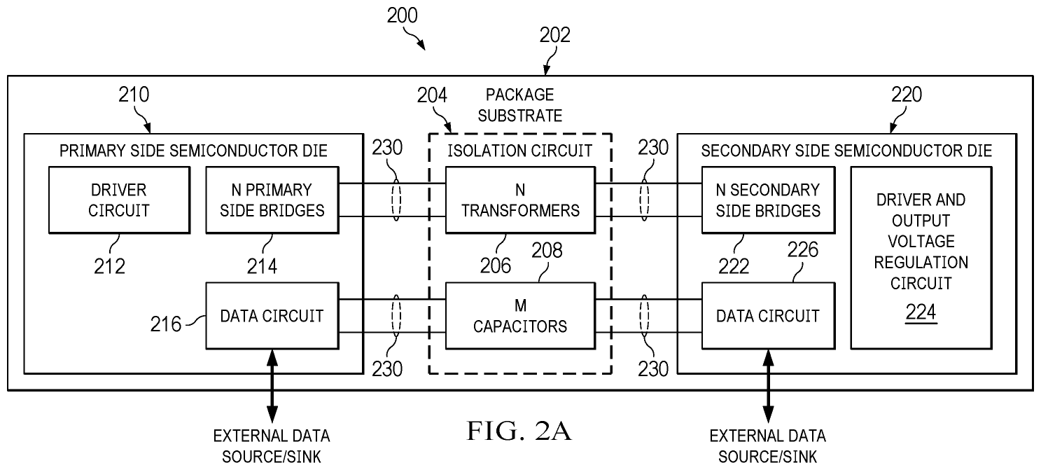

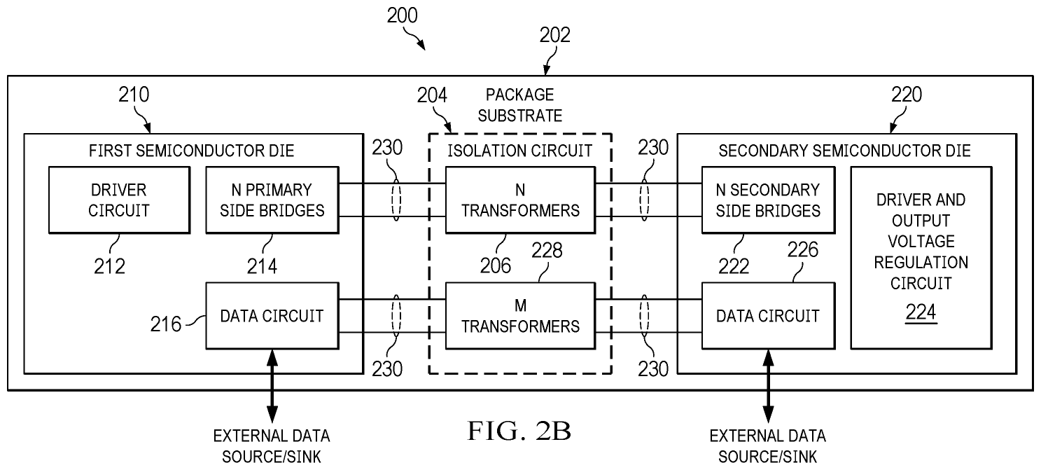

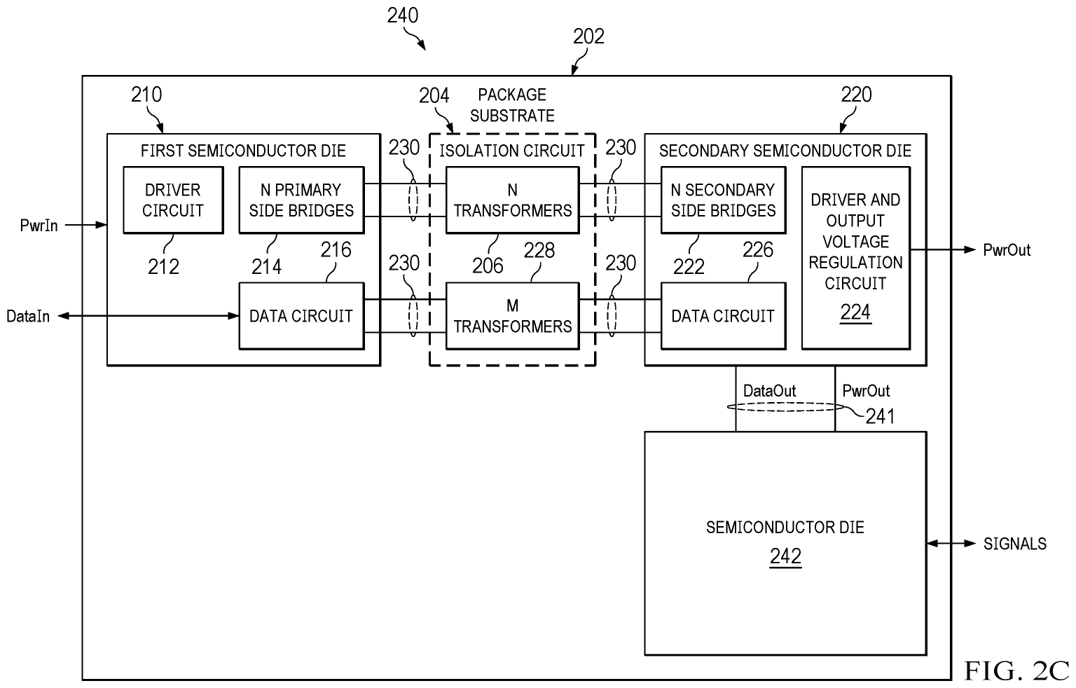

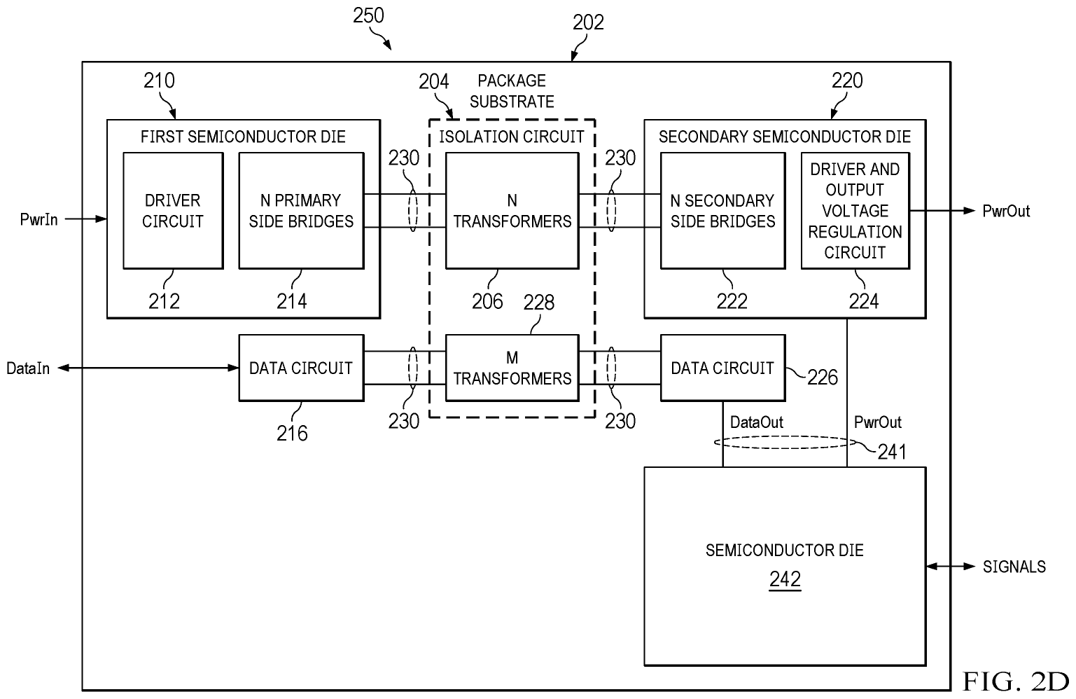

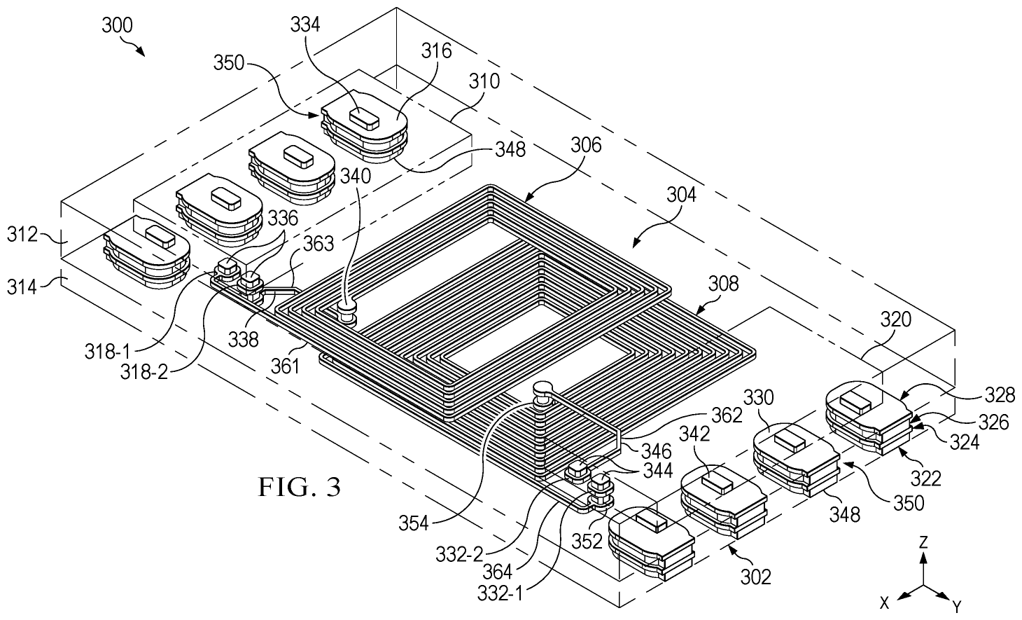

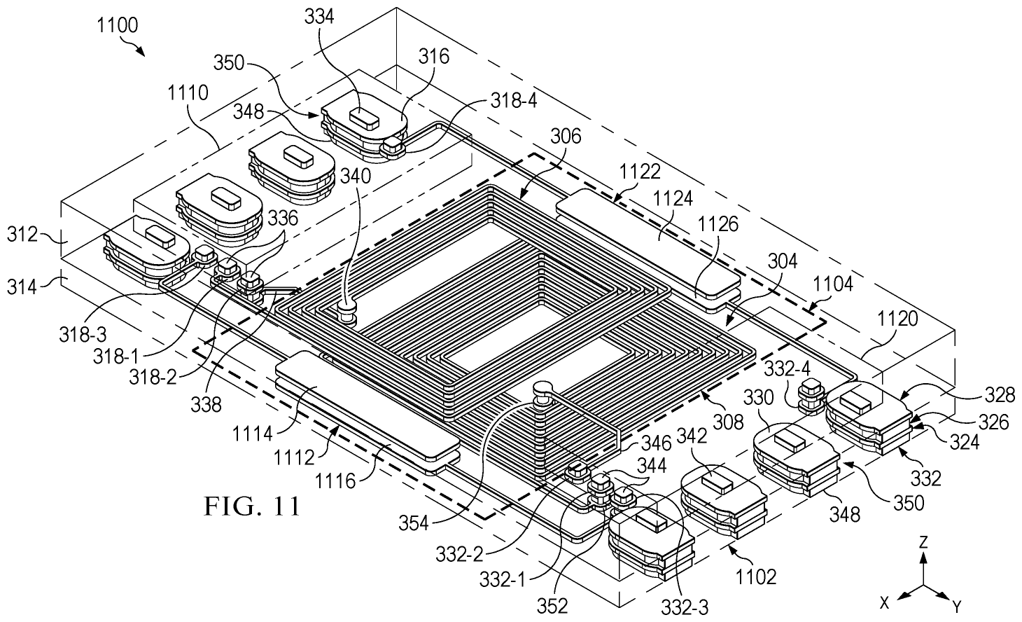

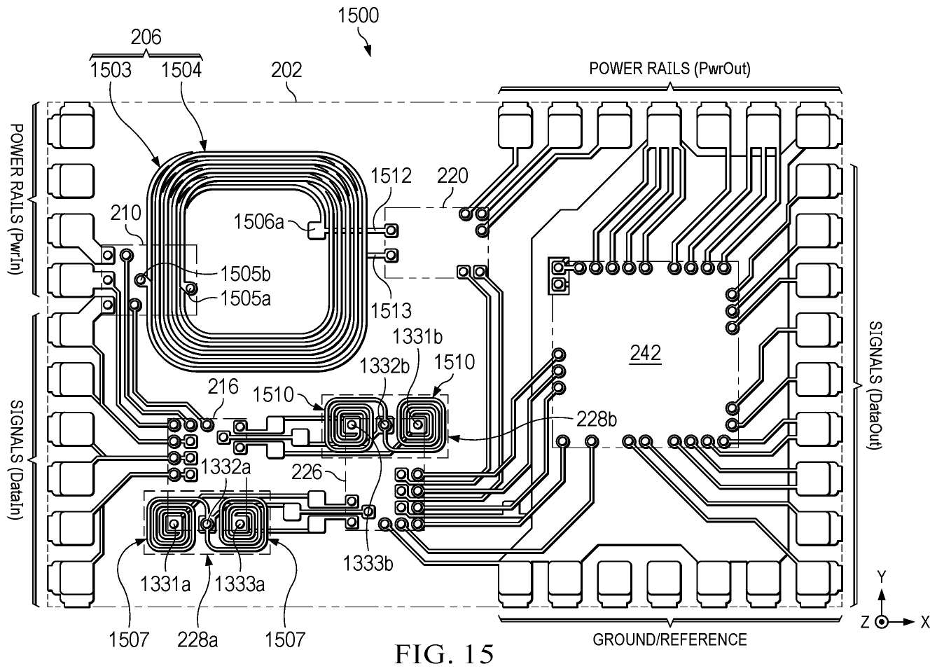

In at least one example, isolation circuit 108 may include one or more isolation circuits. In at least one example, isolation circuit 108 includes a single transformer, for instance as shown in FIGS. 3-11. In at least one example, isolation circuit 108 includes a single capacitor. However, in other examples, isolation circuit 108 includes multiple transformers, for instance as shown in FIGS. 15-23, multiple capacitors, or a combination of one or more transformers and capacitors, for instance as shown in FIGS. 2A and 11.

FIG. 2A is a schematic depicting another example of a packaged IC 200 having an integrated isolation circuit 204. In at least one example, packaged IC 200 includes a package substrate 202, a primary side circuit 210, and a secondary side circuit 220. In at least one example, primary side circuit 210 and secondary side circuit 220 are semiconductor dies. Semiconductor dies 210 and 220 are mounted to package substrate 202. In at least one example, package substrate includes fiberglass-based materials that use etched copper layers and drilled vias instead of electroplated layers and vias. In at least one example, integrated isolation circuit 204 is integrated into layers (not shown) of package substrate 202, as indicated by dashed lines. Moreover, package substrate 202 includes contact pads (not shown) and metallic interconnects 230 (eight shown) to allow interconnectivity between semiconductor dies 210 and 220 and integrated isolation circuit 204. Each interconnect 230 may represent one or more electrical traces and/or vias.

In at least one example, integrated isolation circuit 204 includes both transformers and capacitors. Namely, integrated isolation circuit 204 includes N transformers 206 and M capacitors 208, where both N and M are integer values of one or more. Moreover, N and M may be the same or a different integer value. In at least one example, integrated isolation circuit 204 includes multiple transformers and no capacitors, which may be used to communicate power. In at least one example, integrated isolation circuit 204 includes multiple capacitors and no transformer, which may be used to communicate data, power, or a combination of both.

Primary side semiconductor die 210 is coupled to a primary winding (not shown) of each of the N transformers 206, and includes driver circuit 212, N primary side bridges 214 (e.g., half-bridge or full bridge circuits), and a data circuit 216 (e.g., digital communicator). Data circuit 216 can be on the same semiconductor die or a separate semiconductor die from driver circuit 212 and bridges 214. Any suitable circuit configuration may be used for driver circuit 212, primary side bridges 214, and data circuit 216. Each of the N primary side bridges 214 is coupled to the primary winding (not shown) of a respective one of the N transformers 206 by a respective interconnect 230 of package substrate 202. Driver circuit 212 provides a control function to primary side bridges 214. In turn, each of the primary side bridges 214 provides a voltage to a respective one of N transformers 206 using a respective one of interconnects 230. The current example includes two primary side bridges 214 and two transformers 206, as illustrated by the two interconnects 230 coupled therebetween.

The current example further includes two capacitors 208, as illustrated by the two interconnects 230 coupled between data circuit 216 and M capacitors 208. The two capacitors 208 and interconnects 230 allow bidirectional data communication, for example controller area network (CAN) or CAN flexible data rate (FD) protocol communication or RS-485 protocol communication. Namely, data circuit 216 may provide a data signal to one of the two capacitors 208 and receive a data signal from the other capacitor 208 over respective interconnects 230.

As further illustrated, secondary side semiconductor die 220 includes N secondary side bridges 222, driver and output voltage regulation circuit 224, and a data circuit 226 (e.g., a digital communicator). Data circuit 226 can be on the same semiconductor die or a separate semiconductor die from driver circuit 224 and bridges 222. Any suitable circuit configuration may be used for secondary side bridges 222, driver and output voltage regulation circuit 224, and data circuit 226. Each of N secondary side bridges 222 is coupled to the secondary winding (not shown) of a respective one of N transformers 206 by a respective interconnect 230 of package substrate 202. Driver circuit 224 provides a control function to secondary side bridges 222. In turn, each of secondary side bridges 222 receives a voltage from a respective one of N transformers 206 using a respective one of interconnects 230. An output voltage regulator (VR) of circuit 224 receives and regulates the voltage from secondary side bridges 222, for instance using a feedback loop. The current example includes two secondary side bridges 222 and two transformers 206, as illustrated by two interconnects 230 coupled therebetween.

The example shown in FIG. 2A further includes two capacitors 208, as illustrated by the two interconnects 230 coupled between data circuit 226 and capacitors 208. In at least one example, the two capacitors 208 and interconnects 230 allow bidirectional data communication. Namely, data circuit 226 may provide a data signal to one of the two capacitors 208 and receive a data signal from the other capacitor 208 over respective interconnects 230.

FIG. 2B is a schematic illustrating a packaged IC 220 having an integrated isolation circuit including inductive isolation channels coupled to first semiconductor die 210 and second semiconductor die 220, in accordance with at least one example. Here, M capacitors 208 are replaced with M transformers 228. In at least one example, M transformers 228 have M primary windings and M secondary windings, where the primary windings are coupled to data circuit 216 via interconnects 230 while the secondary windings are coupled to data circuit 226.

In at least one example, data circuit 216 may provide a first data signal to the primary windings of M transformers 228 and receive a second data signal from the secondary windings of M transformers over respective interconnects 230. In at least one example, the first data signal may originate from an external data source, and the second data signal may target an external data sink. In at least one example, the number of primary windings of transformer 228 is equal to the number of secondary windings of transformer 228. In at least one example, the number of primary windings of transformer 228 is different from the number of secondary windings of transformer 228. In at least one example, the size of transformer 228 is smaller than the size of transformer 206. In at least one example, transformer 228 resides within a footprint of transformer 206 (e.g., within a footprint of the windings of transformer 206). In at least one example, transformer 228 is outside the footprint of transformer 206. In at least one example, transformer 228 can be used for bi-directional or uni-directional data transfer unrelated to the power converter formed by driver circuit 212, N primary side bridges 214, N secondary side bridges 222, and driver and output VR circuit 224. One such use of transformer 228 for both data and power circuits is discussed by U.S. patent application Ser. No. 17/363,470, filed Jun. 30, 2021, titled “Data Transfer Through An Isolated Power Converter,” which is incorporated by reference in its entirety. In at least one example, transformer 228 is used for bi-directional or uni-directional data transfer directly related to controlling of the power converter formed by driver circuit 212, N primary side bridges 214, N secondary side bridges 222, and driver and output VR circuit 224. Transformer 228 may include two or more transforms, one for each data or signal line.

FIG. 2C is a schematic illustrating a packaged IC 240. In FIG. 2C, primary side semiconductor die 210 is in a first semiconductor die including data circuit 216, and secondary side semiconductor die 220 is in a second semiconductor die including data circuit 226. Packaged IC 240 also includes a third semiconductor die 242 on package substrate 202 and coupled to second semiconductor die 220, in accordance with at least one example. In at least one example, third semiconductor die 242 can be mounted on package substrate 202 prior to formation of the integrated isolation circuit in package substrate 202. In at least one example, third semiconductor die 242 can be electrically connected to package substrate 202 via bond wires. In at least one example, semiconductor die 242 receives data (DataOut) and power (PwrOut), together indicated by interconnects 241, from semiconductor die 242. DataOut is an output of data circuit 226 while PwrOut is an output of VR circuit 224 of second semiconductor die 220. In at least one example, semiconductor die 242 is part of an application specific integrated circuit (ASIC). Examples of ASIC include analog-to-digital converter (ADC), digital-to-analog converter (DAC), equalizer, digital filter, microcontroller, etc. Semiconductor die 242 can be flip-chip mounted, wire-bonded, or of any other package mounting technology.

FIG. 2D is a schematic illustrating a packaged IC 250 having third semiconductor die 242 coupled to second semiconductor die 220, and where data circuits 216 and 226 are separate semiconductor dies from semiconductor dies 210 and 220, in accordance with at least one example. Here, semiconductor dies 210 and 220 can form a DC-DC converter or power regulation, and data circuits 216 and 226 provide data communication. First semiconductor die 210 includes driver circuit 212 and N primary side bridges 214. Second semiconductor die 220 includes N secondary side bridges 222 and driver and output VR circuit 224.

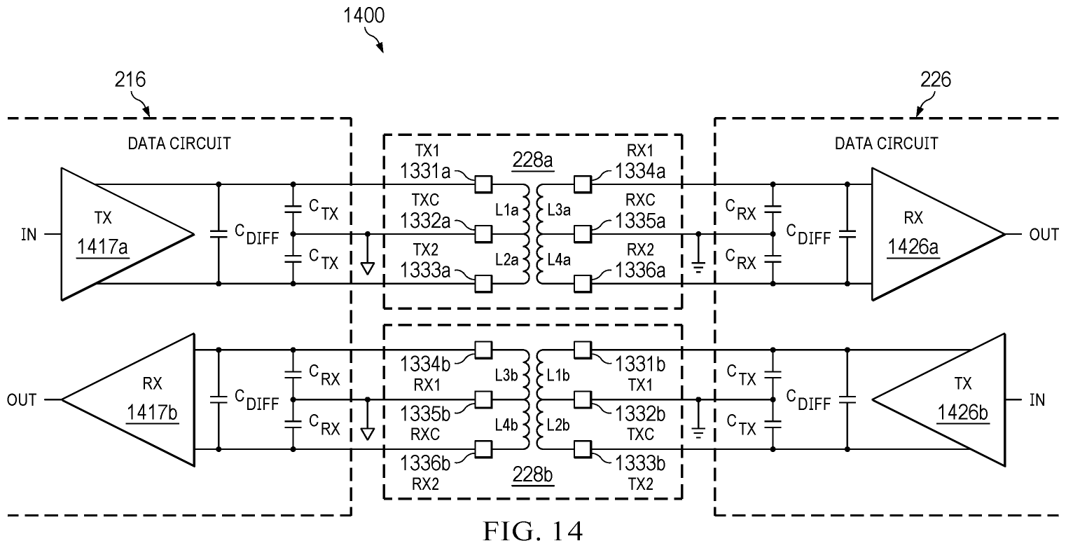

In at least one example, data circuit 216 and data circuit 226 provide data communication signals (e.g., DataOut) that may be used for digital control or feedback control of DC-DC converter formed by first semiconductor die 210 and second semiconductor die 220. DataOut and DataIn may be bidirectional signals. In at least one example, data circuit 216 and/or data circuit 226 provide data communication signals to semiconductor die 242 and also provide data control signals to first semiconductor die 210 and second semiconductor die 220 for feedback control of DC-DC converter. FIGS. 14-24 provide circuit and structure details of examples of FIGS. 2B-D.

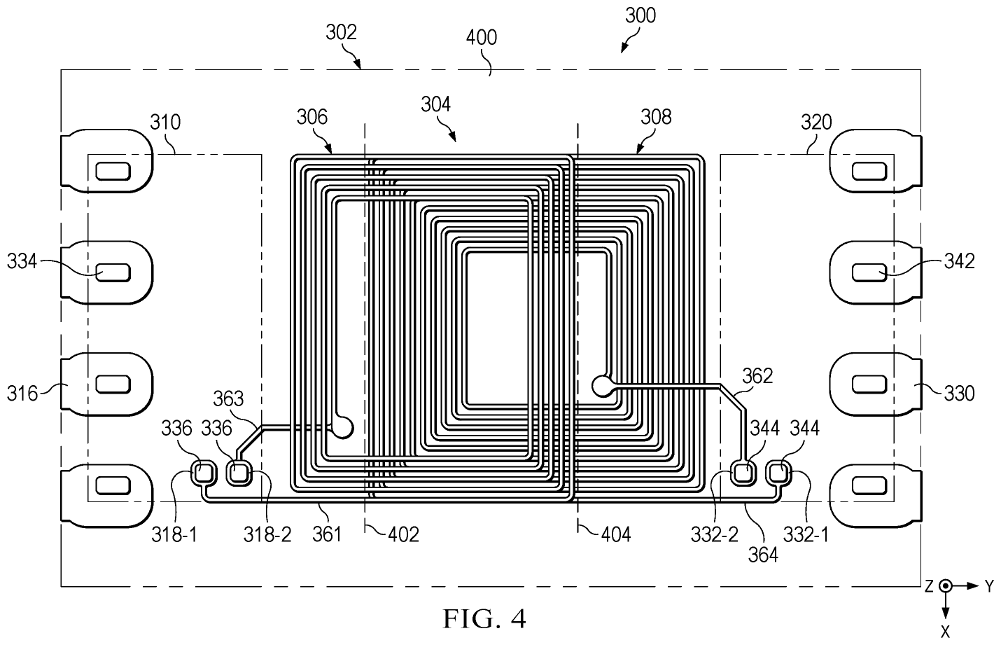

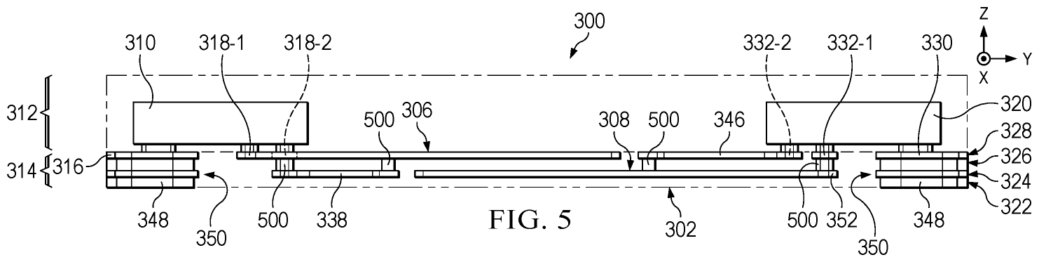

FIGS. 3-5 are schematics that illustrate different views of an example IC package (or packaged IC) 300 having integrated isolation circuit 304, according to some examples. More particularly, FIG. 3 is a schematic that shows an isometric view of packaged IC 300 along the XYZ axes. FIG. 4 is a schematic that shows a top-down plan view of packaged IC 300 along the XY axes, and FIG. 5 is a schematic that shows a side view of packaged IC 300 along the YZ axes.

As illustrated, packaged IC 300 includes a package substrate 302 (e.g., a circuit support structure) and two semiconductor dies 310 and 320 mounted to a surface (400 in FIG. 4) of package substrate 302. The material, structure, and function of package substrate 302 may be similar to the material, structure, and function of package substrate 202. In an example, semiconductor die 310 includes driver circuit and a primary side bridge circuit, and semiconductor die 320 includes a secondary side bridge circuit and driver/output voltage regulation circuit, for instance as described previously as primary side semiconductor die 210 (first semiconductor die) and secondary side semiconductor die 220 (second semiconductor die) by reference to FIGS. 2A-D. In at least one example, packaged IC 300 further includes a mold compound 312 that encapsulates semiconductor dies 310 and 320 and surface 400 of package substrate 302. In at least one example, mold compound 312 may have any suitable form such as a bulk mold compound, a sheet mold compound, an insulation build-up film, etc. In at least one example, packaged IC 300, including package substrate 302 and semiconductor dies 310 and 320, is or forms a flat no-leads package, in particular a dual-flat no-leads (DFN) package. In at least one example, contact pads 348 used to mount packaged IC 300 to an external package substrate are arranged such that packaged IC 300 forms a quad-flat no-leads (QFN) package.

In at least one example, package substrate 302 is constructed to include metal layers 322-328 and isolation material 314 containing or encapsulating metal layers 322-328. In an example, package substrate 302 is a multi-layer structure made using routable lead frame (RLF) technology. A metal layer, as used herein, is a layer of metal within which is formed metallic elements of a package substrate such as contact pads, vias, electrical traces, a thermal/ground pad, and circuit elements of isolation circuit. Metal layers are positioned in substantially parallel planes to one another and are substantially planar within allowable tolerances as defined by the technology used to make the package substrate. Any suitable metal may be used to form the metal layers, such as copper, aluminum, and gold. Package substrate 302, in this example, includes four metal layers 322-328. However, other example package substrates may include more or fewer metal layers.

Isolation material 314 is used to electrically isolate metal layers 322-328 and may, thereby, include a dielectric or insulator. Isolation material 314 fully contains some metal layers 322-328 and partially contains other metal layers 322-328. Partially containing a metal layer includes, for instance, when contact pads formed in a metal layer are exposed at a surface of package substrate 302. Moreover, isolation material 314 defines a mounting or top surface 400 and an opposing or bottom surface (not shown) to mounting surface 400. In at least one example, isolation material 314 is a mold compound having any suitable form such as a bulk mold compound, a sheet mold compound, an insulation build-up film, etc., and may be or include the same or a different type of mold compound as mold compound 312. In a particular example, isolation material 314 is composed of Ajinomoto build-up film (ABF). Other isolation materials may be used, such as ceramic or fiberglass-based material.

As further illustrated in FIG. 3, package substrate 302 also includes isolation circuit 304, which is formed and integrated therein. Isolation circuit 304 may have a similar function as described with reference to integrated isolation circuit 204 with reference to FIGS. 2A-D. In this example, isolation circuit 304 includes a single transformer having a winding 306 (e.g., a primary winding) as a first circuit element and a winding 308 (e.g., a secondary winding) as a second circuit element. Accordingly, integrated isolation circuit 304 is also referred to herein as transformer 304. In at least one example, integrated isolation circuit 304 may include a single capacitor having a first set of one or more plates as a first circuit element and a second set of one or more plates as the second circuit element integrated into package substrate 302.

In at least one example, windings 306 and 308 are formed in different ones of metal layers 322-328 as further described below and illustrated by reference to FIG. 5. Moreover, windings 306 and 308 are electrically isolated using the isolation material 314 of package substrate 302, which in one particular example forms a galvanic isolation barrier between two different power domains. In at least one example, first semiconductor die 310 is powered using a voltage supply and ground connection associated with a first power domain. Second semiconductor die 320 is powered using a different voltage supply and ground connection associated with a second power domain. Moreover, in at least one example, isolation material 314, e.g., the mold compound, has a thickness and is a type that provides a galvanic isolation barrier that can withstand 5 kilovolts (kV) root mean square (RMS) for 60 seconds in one example and 2.5 kV RMS for 60 seconds in another example. However, different isolation ratings may be achievable based at least in part on the type and thickness of isolation material 314 used.

Using a mold compound as isolation material 314, instead of a laminate, allows for a smaller critical separation between windings 306 and 308 while maintaining the same voltage insulation and allows for improved thermal performance of isolation circuit 304. Also, making package substrate 302 using routable lead frame technology allows for thicker copper traces (e.g., 30-35 micrometers or thicker, for instance 1%, 5%, or 10% thicker) and smaller metal width and spacing (e.g., 30×30 micrometers² or less, for instance 1%, 5%, or 10% less). This may lead to an improved efficiency of transformer 304 by allowing an increased quality factor for transformer 304. Also, integrating transformer 304 into package substrate 302 allows for smaller packaged IC sizes (e.g., 5.0×3.0×0.8 millimeters³ or less, for instance 1%, 5%, or 10% less).

As used herein, critical separation means one or more minimum distances taken between first and second circuit elements (e.g., primary and secondary windings or first and second capacitor plates) of an isolation circuit that allows a given isolation rating to be achieved without a voltage breakdown of the isolation material between the first and second circuit elements. Accordingly, by using different types of isolation material 314, e.g., different types of mold compounds individually or in combination, the critical separation between windings 306 and 308 can be adjusted, for instance to meet desired creepage and clearance for packaged IC 300 and to achieve lower creepage and clearance than achievable using laminate as isolation material.

In at least one example, package substrate 302 includes a first plurality of contact pads 316 (one of four labeled) and 318 (individually referred to as contact pads 318-1 and 318-2) for coupling to semiconductor die 310. In at least one example, package substrate 302 further includes a second plurality of contact pads 330 (one of four labeled) and 332 (individually referred to as contact pads 332-1 and 332-2) for coupling to second semiconductor die 320. More particularly, contact pads 316, 318, 330, and 332 are formed in metal layer 328 (e.g., a top metal layer) and are exposed at mounting surface 400 of package substrate 302 for coupling to semiconductor dies 310 and 320. Contact pads 316, 318, 330, and 332 are, thereby, also referred to herein as IC contact pads as they are used for mounting or securing and electrically coupling semiconductor dies 310 and 320 to package substrate 302.

Contact pads 316 and 330 are coupled to contacts pads 348 (two of eight labeled), which are formed in metal layer 322 (e.g., a bottom metal layer) and exposed at a bottom surface (not shown) of package substrate 302. In a DFN or QFN implementation of packaged IC 300, for instance, bottom metal layer 322 may also have formed therein a ground/thermal plane to allow improved thermal performance of packaged IC 300.

Referring to FIG. 4, in this example, mounting surface 400 and the opposing bottom surface are substantially flat or planar and are substantially parallel to one another within allowable tolerances of the technology used to make package substrate 302. The electrical coupling between contact pads 316 and 348 and between contact pads 330 and 348 is implemented using vias 350 (two of eight labeled) formed in intervening metal layers 324 and 326 and formed through the isolation material 314. Accordingly, contact pads 348 may be used to mount and couple packaged IC 300 to an external package substrate, such as a laminate PCB.

Contact pads 318 and 332 are coupled to transformer 304. As shown, contact pad 318-1 forms a first input voltage terminal for winding 306. Contact pad 318-2 is coupled to a second input voltage terminal 340 for winding 306 using an electrical trace 338 and two vias (500 in FIG. 5). As further shown, contact pad 332-1 is coupled to a first output voltage terminal 352 for winding 308 using a via 500. Contact pad 332-2 is coupled to a second output voltage terminal 354 for winding 308 using an electrical trace 346 and a via 500. In at least one example, vias 500 are formed in metal layer 326 through the isolation material 314.

By reference to FIGS. 3 and 4, contact pads 316 and 318 are used to flip-chip mount semiconductor die 310 onto mounting surface 400. Namely, contact pads 334 (one of four labeled) on a surface of semiconductor die 310 are mechanically coupled to contact pads 316, for instance using solder balls (not shown) that may be attached to contact pads 334. Contact pads 336 also on the surface of semiconductor die 310 are mechanically and coupled to contact pads 318, for instance using solder balls (not shown) that may be attached to contact pads 336. The coupling between contact pads 318 and 336 allows circuit, such as a bridge circuit, on semiconductor die 310 to be coupled to primary winding 306 of transformer 304.

Additionally, contact pads 330 and 332 are used to flip-chip mount semiconductor die 320 onto mounting surface 400. Namely, contact pads 342 (one of four labeled) on a surface of semiconductor die 320 are mechanically and coupled to contact pads 330, for instance using solder balls (not shown) that may be attached to the contact pads 342. Contact pads 344 also on the surface of semiconductor die 320 are mechanically and coupled to contact pads 332, for instance using solder balls (not shown) that may be attached to contact pads 344. The coupling between contact pads 332 and 344 allows circuit, such as a bridge circuit, on semiconductor die 320 to be coupled to secondary winding 308 of transformer 304. In another example, instead of flip-chip mounting, semiconductor dies 310 and 320 are mounted to surface 400 of package substrate 302 using wire bonding.

As further illustrated in FIGS. 3 and 4, windings 306 and 308 of transformer 304 partially overlap. As such, at least a portion of each of windings 306 and 308 is non-overlapping. Accordingly in this example, and as shown by reference to FIG. 4, a portion of winding 306 to the left of dotted line 402 is non-overlapping. Also, a portion of winding 308 to the right of dotted line 404 is non-overlapping. Having partially overlapping windings 306 and 308 allows semiconductor die 310 to be coupled to winding 306 and semiconductor die 320 to be coupled to winding 308 without the use of wire bonding. The elimination of bond wires in packaged IC 300, with partially overlapping windings 306 and 308 and flip-chip mounting, allows reduced interconnection parasitic, e.g., reduced parasitic inductance, in the package. This mitigates the inclusion of one or more large decoupling capacitors within packaged IC 300 or within a system that contains packaged IC 300.

As shown in FIGS. 3 and 5, elements of package substrate 302, which are associated with transformer 304 and with coupling transformer 304 to semiconductor dies 310 and 320, can be formed in two metal layers. Namely, winding 306, electrical trace 346, and contact pads 316, 318, 330, and 332 are formed in top metal layer 328. Moreover, winding 308 and electrical trace 338 are formed in metal layer 324. The spacing between metal layers 328 and 324 from removing metal layer 326 (except for its use in vias 350 and 500) allows for a vertical isolation separation of windings 306 and 308, in an example, of 105 micrometers or less while maintaining a voltage isolation of 2.5 kV RMS for 60 seconds.

As shown in FIG. 3, first interconnect 361 couples primary-side windings 306 to contact pad 318-1 for coupling to first semiconductor die 310. Second interconnect 362 couples secondary-side windings 308 to contact pad 332-2 for coupling to second semiconductor die 320. Third interconnect 363, which includes electrical trace 338, couples primary-side windings 306 to contact pad 318-2 for coupling to first semiconductor die 310. Fourth interconnect 364 couples secondary-side windings 308 to contact pad 332-1 for coupling to second semiconductor die 320. Any suitable conductive material may be used for forming first interconnect 361, second interconnect 362, third interconnect 363, and fourth interconnect 364. In at least one example, first interconnect 361 and second interconnect 362 (which can include electrical trace 346) are on a first metal layer (e.g., metal layer 328) of packaged substrate 302, and third interconnect 363 and fourth interconnect 364 are on a second metal layer (e.g., metal layer 324) of packaged substrate 302 below the first metal layer.

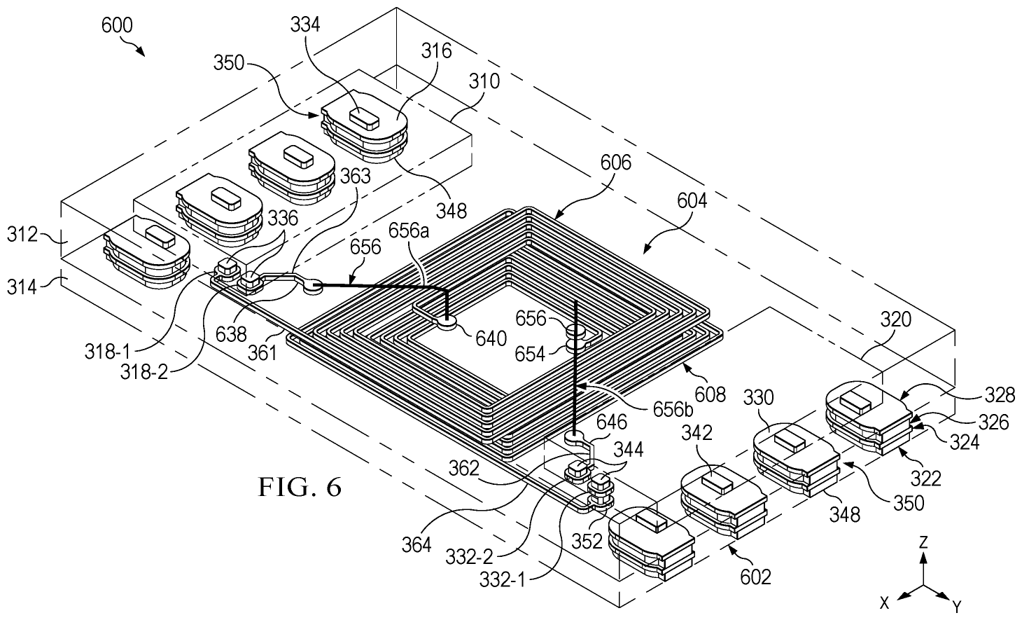

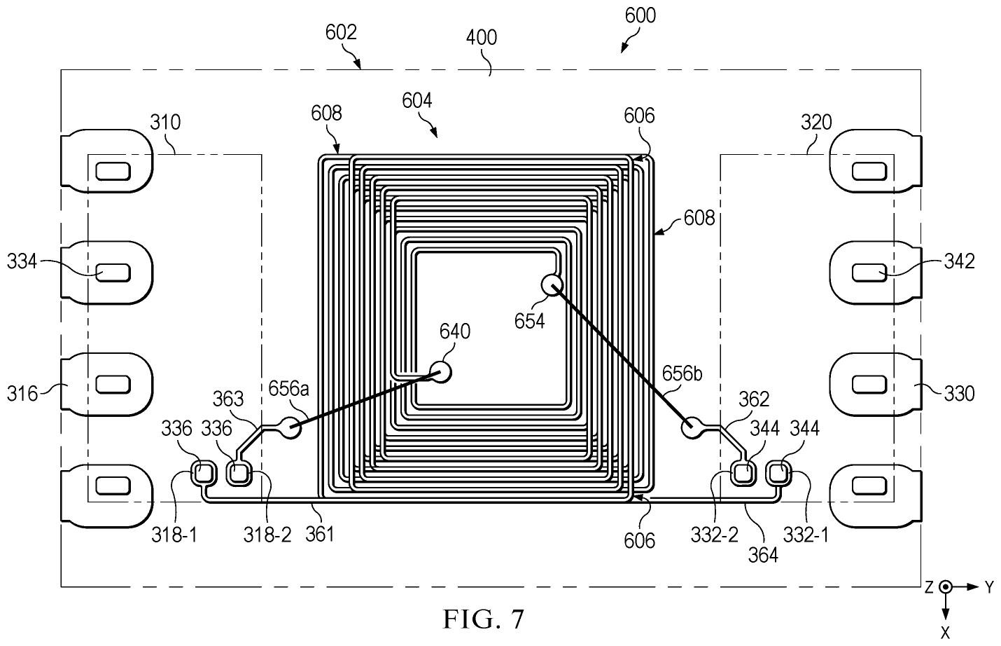

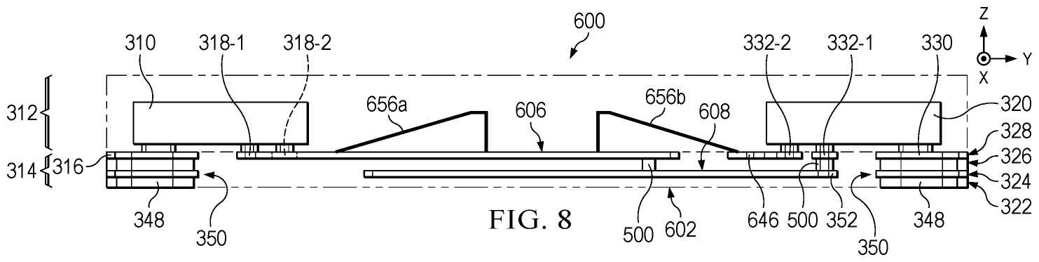

FIGS. 6-8 are schematics that illustrate different views of another example packaged IC 600 having integrated isolation circuit 604, according to at least some examples. More particularly, FIG. 6 is a schematic that illustrates an isometric view of packaged IC 600 along the XYZ axes. FIG. 7 is a schematic that illustrates a top-down plan view of packaged IC 600 along the XY axes, and FIG. 8 is a schematic that illustrates a side view of packaged IC 600 along the YZ axes.

As illustrated, packaged IC 600 includes a package substrate 602 and two semiconductor dies 310 and 320 mounted to a surface (400 in FIG. 7) of package substrate 602. In at least one example, package substrate 602 includes isolation circuit 604 integrated therein. packaged IC 600 is similar in some respects to packaged IC 300, as represented by the common reference numbers between FIGS. 3 and 6. However, package substrate 602 of packaged IC 600 differs from package substrate 302 of packaged IC 300 in the design of the single transformer of isolation circuit 604, also referred to herein as transformer 604. Moreover, package substrate 602 differs from package substrate 302 in how contact pads 318 and 332 are coupled to transformer 604 as compared to how contact pads 318 and 332 are coupled to transformer 304.

More particularly, similarly to packaged IC 300, contact pad 318-1 forms a first input voltage terminal for a winding 606 of transformer 604. First interconnect 361 couples primary-side windings 606 to contact pad 318-1. Contact pad 318-2 is coupled to a second input voltage terminal 640 of winding 606 using both third interconnect 363 (which includes an electrical trace 638) and a bond wire 656a (first bond wire). Additionally, similarly to packaged IC 300, contact pad 332-1 is coupled to a first output voltage terminal 352 for a winding 608 of transformer 604 using fourth interconnect 364 and a via (500 in FIG. 8). Also, contact pad 332-2 is coupled to a second output voltage terminal 654 of secondary-side winding 608 using second interconnect 362 (which includes an electrical trace 646), a bond wire 656b (second bond wire), and a via 500. Bond wires 656a and 656b are generally referred to as bond wire 656.

FIG. 7 illustrates that semiconductor dies 310 and 320 are similarly flip-chip mounted to a surface 400 of package substrate 602 as they are to the surface 400 of package substrate 302. By contrast, however, windings 606 and 608 of transformer 604 fully overlap. Namely, as shown, outer borders of winding 606 are fully contained within or align with outer borders of winding 608.

Also, as shown in FIGS. 6 and 8, elements of package substrate 602, which are associated with transformer 604 and coupling transformer 604 to semiconductor dies 310 and 320, can be formed in two metal layers. Namely, winding 606, electrical traces 638 and 646 (first interconnect 361 and second interconnect 362), and contact pads 316, 318, 330, and 332 are formed in top metal layer 328. Moreover, winding 308 is formed in metal layer 324, which is below top metal layer 328.

By comparison to packaged IC 300, the use of bond wires 656 may increase the parasitic inductance in packaged IC 600. However, the fully overlapping windings 606 and 608 may allow transformer 604 to occupy a smaller area on package substrate 602, thereby allowing a smaller size for packaged IC 600 over packaged IC 300. Moreover, the arrangement of transformer 604 illustrated in FIGS. 6-8 allows an increase in coupling within transformer 604. This, resultantly, allows high power transfer and higher DC-DC efficiency as compared to transformer 304 arrangement illustrated in FIGS. 3-5.

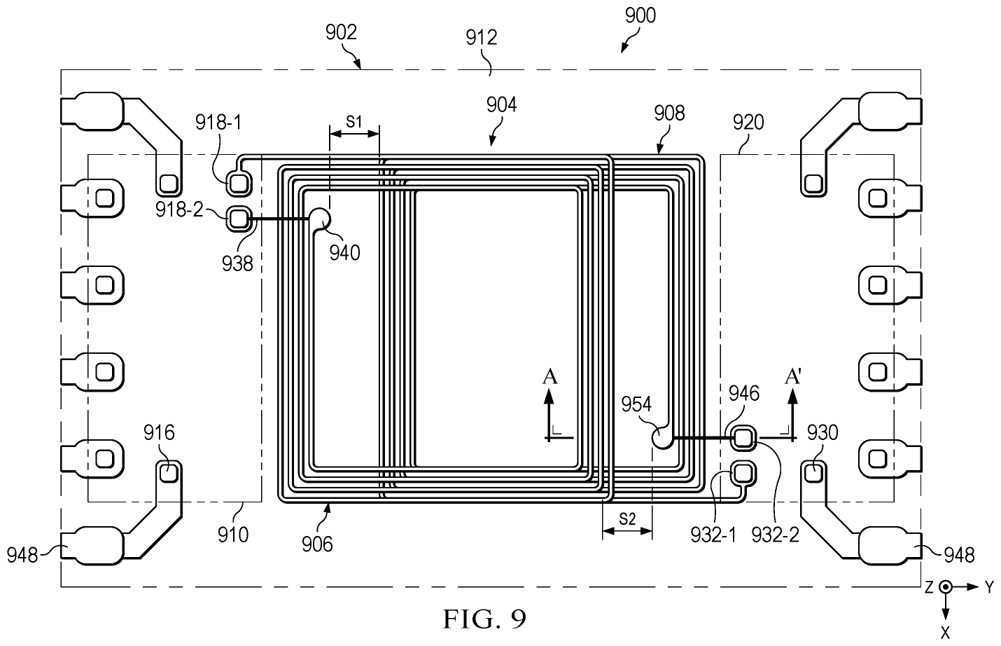

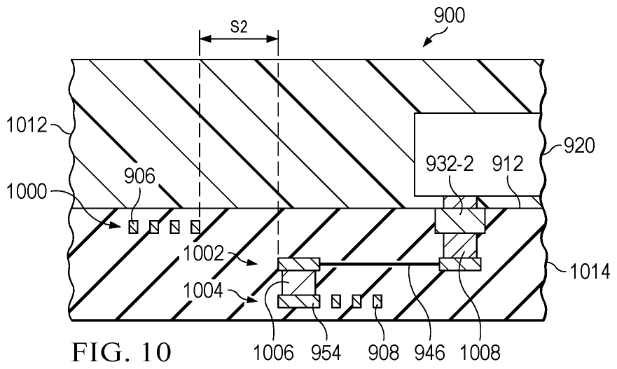

FIGS. 9-10 are schematics that illustrate different views of another example packaged IC 900 having integrated isolation circuit 904, according to at least one example. More particularly, FIG. 9 is a schematic that illustrates a top-down plan view of packaged IC 900, and FIG. 10 is a schematic that illustrates a partial cross-sectional view taken at dashed line AA′ through packaged IC 900.

As illustrated, packaged IC 900 includes a package substrate 902 and two semiconductor dies 910 and 920 mounted to a surface 912 of package substrate 902. Here, package substrate 902 may have similar features and function as package substrate 202. In at least one example, semiconductor die 910 includes driver circuit and a primary side bridge circuit, and semiconductor die 920 includes a secondary side bridge circuit and driver/output voltage regulation circuit, for instance as described previously as first semiconductor die 210 (e.g., primary side die) and second semiconductor die 220 (e.g., secondary side die) by reference to FIGS. 2A-D. Packaged IC 900 further includes a mold compound (1012 of FIG. 10) that encapsulates semiconductor dies 910 and 920 and surface 912 of package substrate 902. In at least one example, mold compound 1012 may have any suitable form such as a bulk mold compound, a sheet mold compound, an insulation build-up film, etc.

In at least one example, package substrate 902 is constructed to include multiple metal layers (e.g., 1000-1004 of FIG. 10) and isolation material (1014 of FIG. 10) containing or encapsulating the metal layers 1000-1004. In at least one example, package substrate 902 is constructed to include four metal layers, although only three are shown in FIG. 10. The fourth metal layer may have formed therein contacts pads 948 to couple packaged IC 900 to an external package substrate such as a PCB and may also have formed therein a thermal/ground pad. In at least one example, packaged IC 900 may be constructed from more or fewer than four metal layers. Metal layers 1000-1004 are positioned in substantially parallel planes to one another and are substantially planar within allowable tolerances as defined by the technology used to make package substrate 902. Any suitable metal may be used to form metal layers 1000-1004, such as copper.

Isolation material 1014 is used to electrically isolate the metal layers 1000-1004 and may, thereby, include a dielectric or insulator. Isolation material 1014 fully contains some metal layers 1000-1004 and partially contains other metal layers 1000-1004. Moreover, isolation material 1014 defines a mounting or top surface 912 and an opposing or bottom surface (not shown) to mounting surface 912. In at least one example, isolation material 1014 is a mold compound having any suitable form such as a bulk mold compound, a sheet mold compound, an insulation build-up film, etc., and may be or include the same or a different type of mold compound as mold compound 1012. In at least one example, isolation material 1014 is composed of ABF.

As further illustrated in FIG. 9, package substrate 902 also includes isolation circuit 904, which is formed and integrated therein. In this example, isolation circuit 904 includes a single transformer having a winding 906 (e.g., a primary winding) as a first circuit element and a winding 908 (e.g., a secondary winding) as a second circuit element. Accordingly, isolation circuit 904 is also referred to herein as transformer 904. As further shown, windings 906 and 908 of transformer 904 partially overlap.

Windings 906 and 908 are formed in different ones of metal layers 1000-1004 as further described below and illustrated by reference to FIG. 10. Moreover, windings 906 and 908 are electrically isolated using isolation material 1014 of package substrate 902, which in one example forms a galvanic isolation barrier between two different power domains used to separately power semiconductor dies 910 and 920.

In at least one example, package substrate 902 includes a first plurality of contact pads 916 (one of six labeled) and 918 (individually referred to as contact pads 918-1 and 918-2) for coupling to semiconductor die 910. In at least one example, contact pads 916 and 918 are used to flip-chip mount semiconductor die 910 onto mounting surface 912, for instance using contact pads and solder balls (not shown) coupled to a surface of semiconductor die 910. In at least one example, package substrate 902 further includes a second plurality of contact pads 930 (one of six labeled) and 932 (individually referred to as contact pads 932-1 and 932-2) for coupling to semiconductor die 920. In at least one example, contact pads 930 and 932 are used to flip-chip mount semiconductor die 920 onto mounting surface 912, for instance using contact pads and solder balls (not shown) coupled to a surface of semiconductor die 920.

In at least one example, contact pads 916, 918, 930, and 932 are formed in metal layer 1000 (e.g., a top metal layer) and are exposed at mounting surface 912 of package substrate 902 to couple to semiconductor dies 910 and 920. In at least one example, instead of flip-chip mounting, semiconductor dies 910 and 920 are mounted to surface 912 of package substrate 902 using bond wires.

Contact pads 916 and 930 are coupled to contacts pads 948 (two of twelve labeled), which are formed in a bottom metal layer (not shown) and exposed at a bottom surface (not shown) of package substrate 902. In at least one example, mounting surface 912 and the opposing bottom surface are substantially flat or planar and are substantially parallel to one another within allowable tolerances of the technology used to make package substrate 902. The electrical coupling between contact pads 916 and 948 and between contact pads 930 and 948 may be implemented using vias (not shown) formed in intervening metal layers 1002 and 1004 and formed through the isolation material 1014. Accordingly, contact pads 948 may be used to mount and couple packaged IC 900 to an external package substrate, such as a laminate PCB.

Contact pads 918 and 932 are coupled to transformer 904. As shown, contact pad 918-1 forms a first input voltage terminal for winding 906. Contact pad 918-2 is coupled to a second input voltage terminal 940 for winding 906 using an electrical trace 938 and two vias (not shown), since electrical trace 938 is formed in a different metal layer than winding 906. When semiconductor die 910 is mounted to package substrate 902, a mechanical and electrical coupling between contact pads 918 and contact pads (not shown) on a surface of semiconductor die 910 allows circuit, (e.g., a bridge circuit) on semiconductor die 910 to be coupled to winding 906.

As further shown, contact pad 932-1 is coupled to a first output voltage terminal (not labeled) for winding 908 using a via (not shown), since the contact pad 932-1 and winding 908 are formed in different metal layers. Contact pad 932-2 is coupled to a second output voltage terminal 954 for winding 908 using an electrical trace 946 and vias (1006 and 1008 of FIG. 10) through isolation material 1014. When semiconductor die 920 is mounted to package substrate 902, a mechanical and electrical coupling between contact pads 932 and contact pads (not shown) on a surface of semiconductor die 920 allows circuit (e.g., a bridge circuit), on semiconductor die 920 to be coupled to winding 908.

As partially shown in FIGS. 9 and 10, elements of package substrate 902, which are associated with transformer 904 and with coupling transformer 904 to semiconductor dies 910 and 920, are formed in three metal layers in this example. Namely, winding 906 and contact pads 916, 918, 930, and 932 are formed in top metal layer 1000, and winding 908 is formed in metal layer 1004. However, electrical trace 938 (which couples contact pad 918-2 to winding 906) and electrical trace 946 (which couples contact pad 932-2 to winding 908) are formed in metal layer 1002, which is between metal layers 1000 and 1004.

Forming the electrical traces (e.g., 938 and 946), in a third metal layer instead of the two metal layers in which contact pads 916, 918, 930, and 932 and windings 906 and 908 are formed allows greater control over creating the critical separation, e.g., distances S1 and S2, between windings 906 and 908 to meet a desired voltage isolation rating. As illustrated, S1 is the distance between metal layers 1002 and 1004, and S2 is the distance between metal layers 1000 and 1002. S1 and S2 may be two of many separations that exist within a packaged IC, such as packaged IC 900, which are controlled to achieve a desired isolation rating or performance.

FIG. 11 is a schematic that illustrates an isometric view of another example packaged IC 1100 having integrated isolation circuit 1104. As illustrated, packaged IC 1100 includes a package substrate 1102 and two semiconductor dies 1110 and 1120 mounted to a surface (not shown) of package substrate 1102. Package substrate 1102 includes isolation circuit 1104 integrated therein. packaged IC 1100 is similar in some respects to packaged IC 300, as represented by the common reference numbers between FIGS. 3 and 11. However, packaged IC 1100 differs from packaged IC 300 in the design of semiconductor dies 1110 and 1120 as compared to semiconductor dies 310 and 320. packaged IC 1100 also differs from packaged IC 300 in the design of isolation circuit 1104 and its coupling to semiconductor dies 1110 and 1120 as compared to isolation circuit 304 and its coupling to semiconductor dies 310 and 320.

Namely, in an example, semiconductor dies 210 and 220 shown in and described by reference to FIGS. 2A-D are representative of semiconductor dies 1110 and 1120. Accordingly, semiconductor die 1110 is a primary side circuit, which includes driver circuit, a primary side bridge circuit, and a digital communicator. Semiconductor die 1120 is a secondary side circuit, which includes a secondary side bridge circuit, driver/output voltage regulation circuit, and a digital communicator.

Moreover, in contrast to isolation circuit 304 of packaged IC 300, isolation circuit 1104 of packaged IC 1100 not only includes transformer 304 as an isolation circuit but also includes two additional isolation circuits, capacitors 1112 and 1122. Each of capacitors 1112 and 1122 has two circuit elements (in this case two plates) formed in metal layers 322-328. Namely, capacitor 1112 includes a plate 1114 (e.g., a top plate) and a plate 1116 (e.g., a bottom plate), which is electrically isolated from plate 1114 by isolation material 314. Capacitor 1122 includes a plate 1124 (e.g., a top plate) and a plate 1126 (e.g., a bottom plate), which is electrically isolated from plate 1124 by isolation material 314.

As illustrated, and to reduce the height of packaged IC 1100, top plates 1114 and 1124 are formed in the same metal layer 328 as winding 306. Moreover, bottom plates 1116 and 1126 are formed in the same metal layer 324 as winding 308. In at least one example, parts or all of capacitors 1112 and/or 1122 can be formed in one or more different metal layers than transformer 304. An advantage of embedding isolation capacitors 1112 and 1122 in package substrate 1102 of packaged IC 1100 using a technology such as using routable lead frame technology is that capacitors 1112 and 1122 can be floating with respect to the (external) contact pads 348, which connect to an external circuit such as a PCB. As compared to other packaged IC solutions where, for example, the capacitor structures are mounted on package substrate 1102 along with the ICs requiring additional bond wiring to external contact pins or pads, packaged IC 1100 allows greater flexibility in the electrical coupling of isolation circuit 1104. Additionally, the capability of electrically connecting capacitors 1112 and 1122 without the additional bond wires allows for a reduction in parasitic capacitances. Reduced parasitic capacitances may improve the signal-to-noise ratio and power consumption over the capacitive channels.

Also, in this example, capacitors 1112 and 1122 are vertical plate capacitors with the plates formed parallel to top and bottom surfaces of package substrate 1102. However, in another example, one or both of capacitors 1112 and 1122 can be a lateral plate capacitor with each plate formed in one or more of layers 322-328 and parallel to sides of package substrate 1102. In other examples, each circuit element of capacitors 1112 and 1122 can have multiple connected plates, for instance as with a finger or fringe capacitor.

Also, in contrast to package substrate 302, package substrate 1102 includes an additional two contact pads 318-3 and 318-4 in the first plurality of contact pads, for electrically coupling circuit on semiconductor die 1110 to isolation circuit 1104. Package substrate 1102 also includes an additional two contact pads 332-3 and 332-4 in the second plurality of contact pads, for electrically coupling circuit on semiconductor die 1120 to isolation circuit 1104. As shown, contact pad 318-3 is coupled to plate 1114 of capacitor 1112. Contact pad 318-4 is coupled to plate 1124 of capacitor 1122. Contact pad 332-3 couples to plate 1116 of capacitor 1112. Contact pad 332-4 couples to plate 1126 of capacitor 1122.

Accordingly, when semiconductor die 1110 is flip-chip mounted to package substrate 302, contact pads 336 (two of four labeled) on the surface of semiconductor die 1110 are mechanically and coupled to contact pads 318-3 and 318-4, for instance using solder balls (not shown) that may be attached to contact pads 336. The coupling between contact pads 336 and 318-3, 318-4 allows circuit, such as a digital communicator on the semiconductor die 1110 to be coupled to the top plates of capacitors 1112 and 1122 to facilitate bilateral data communication.

When semiconductor die 1120 is flip-chip mounted to package substrate 302, contact pads 344 (two of four labeled) on the surface of semiconductor die 1120 are mechanically and coupled to contact pads 332-3 and 332-4, for instance using solder balls (not shown) that may be attached to contact pads 344. The coupling between contact pads 344 and 332-3, 332-4 allows circuit, such as a digital communicator on semiconductor die 1120 to be coupled to the bottom plates of capacitors 1112 and 1122 to facilitate bilateral data communication.

As with packaged IC 300, elements of package substrate 1102, which are associated with isolation circuit 1104 and with coupling isolation circuit 1104 to semiconductor dies 1110 and 1120, can be formed in two metal layers. Namely, winding 306, plates 1114 and 1124, electrical trace 346, and contact pads 316, 318, 330, and 332 are formed in top metal layer 328. Moreover, winding 308, plates 1116 and 1126, and electrical trace 328 are formed in metal layer 324.

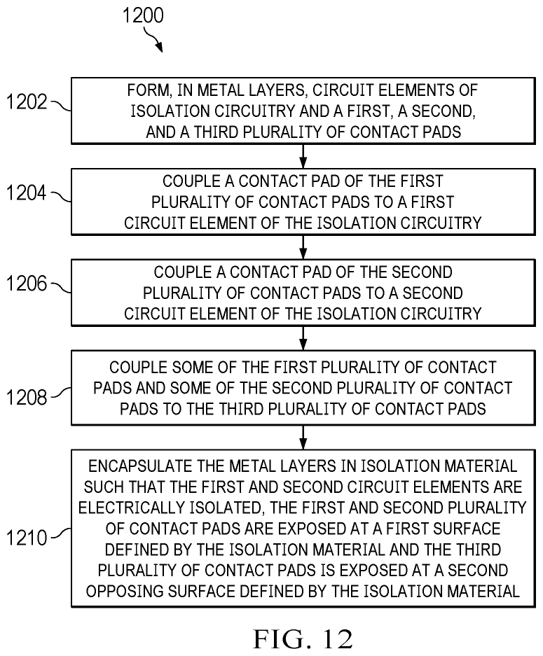

FIG. 12 is a flowchart including blocks 1202-1210 depicting an example method 1200 for making a package substrate/circuit support structure having integrated isolation circuit, for example a package substrate 302, 602, 902, or 1102. However, by way of a particular example, method 1200 is described within the context of making package substrate 302 of FIG. 3. Blocks 1202-1210 of method 1200 need not be performed in the order illustrated in the flowchart. Moreover, method 1200 may be implemented using routable lead frame technology and may be performed as part of a process for manufacturing packaged ICs, such as packaged ICs 300, 600, 900, or 1100.

Block 1202 depicts forming metallic elements of a package substrate in multiple metal layers, such as multiple copper layers. These metallic elements include a first, a second, and a third plurality of contact pads and at least first and second circuit elements of isolation circuit, such as windings of a transformer, plates of a capacitor, or both. In at least one example, the first plurality of contact pads are used to electrically and mechanically couple to a first IC mounted to the package substrate. The second plurality of contact pads are used to electrically and mechanically couple to a second IC mounted to the package substrate. The third plurality of (external) contact pads are used to mount and couple the package substrate to an external structure, such as a PCB.

More particularly, in making package substrate 302 four metal layers 322-328 are used. In accordance with block 1202, windings 306 and 308 of isolation circuit (transformer) 304, a first plurality of contact pads 316 and 318, a second plurality of contact pads 330 and 332, and a third plurality of contact pads 348 are formed in two metal layers 324 and 328 of the four metal layers 322-328.

Block 1204 depicts coupling a contact pad of the first plurality of contact pads to a first circuit element of the isolation circuit. Accordingly, in making package substrate 302, contact pads 318 are coupled to winding 306. Namely, contact pad 318-1 is formed as one voltage input terminal of winding 306. Moreover, electrical trace 338 is formed in metal layer 324, and two vias 500 are formed in metal layer 326 to couple contact pad 318-2 to the other voltage input terminal 340 of winding 306.

Block 1206 depicts coupling a contact pad of the second plurality of contact pads to a second circuit element of the isolation circuit. Accordingly, in making package substrate 302, contact pads 332 are coupled to winding 308. Namely, a via 500 is formed in metal layer 326 to couple contact pad 332-1 to one voltage output terminal 352 of winding 308. Moreover, electrical trace 346 is formed in metal layer 324, and a via 500 is formed in metal layer 326 to couple contact pad 332-2 to the other voltage output terminal 354 of winding 308.

Block 1208 depicts coupling some of the first plurality of contact pads and some of the second plurality of contact pads to the third plurality of contact pads. Accordingly, in making package substrate 302, vias 350 are formed in metal layers 325 and 326 to couple contact pads 316 of the first plurality of contact pads and contact pads 330 of the second plurality of contact pads to the third plurality of contact pads 348.

Block 1210 depicts encapsulating the metal layers in isolation material such that the first and second circuit elements are electrically isolated from each other, the first plurality of contact pads and the second plurality of contact pads are exposed at a first surface defined by the isolation material, and the third plurality of contact pads is exposed at a second opposing surface defined by the isolation material. Accordingly, in making package substrate 302, metal layers 322-328 are encapsulated in isolation material 314, e.g., a mold compound such as ABF. Once encapsulated, isolation material 314 defines a (top/mounting) surface 400 and a (bottom/opposing) surface that is substantially parallel to mounting surface 400. Metal layer 328, or portions thereof, is exposed at the mounting surface 400, including in this example the contact pads 316, 318, 330, 332, winding 306 and electrical trace 346. Metal layer 322, or portions thereof, is exposed at the opposing surface, including in this example contact pads 348. Accordingly, semiconductor die 310 and semiconductor die 320 can be mounted to package substrate 302 and an over mold material 312 added to complete the packaged IC 300.

As shown in FIG. 2A and FIG. 11, in some examples, the isolation circuit of a packaged IC can include a pair of capacitors (e.g., capacitors 208, 1112, and 1122) to provide galvanic isolation for DC current/voltage while allowing differential AC signal (e.g., data signal) transfer. In some other examples, as shown in FIGS. 2B, 2C, 2D, and subsequent figures, the isolation circuit of a packaged IC can include transformers (e.g., transformers 228) to provide galvanic isolation while allowing differential AC data signal transfer.

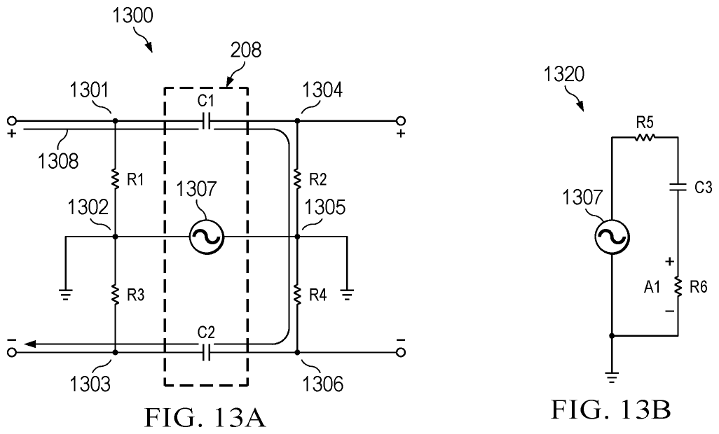

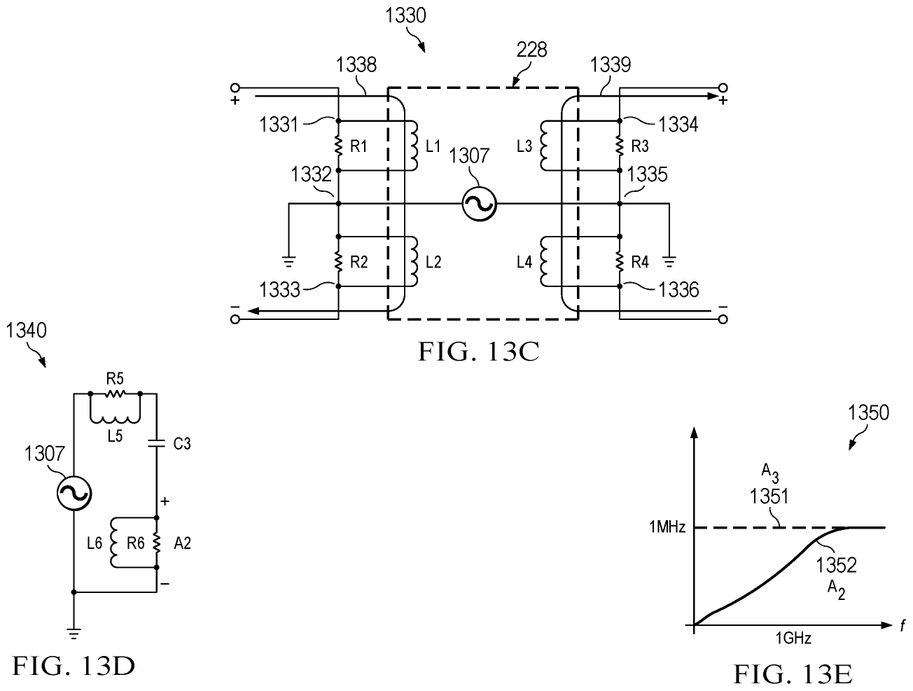

Using transformers for galvanic isolation and differential AC signals transmission can provide various advantages over capacitors. One advantage is improved common mode transient immunity. FIGS. 13A-D are schematics of circuit models of capacitors and transformers that illustrate the improvement in common mode transient immunity provided by transformers over capacitors. Specifically, FIGS. 13A-B are schematics showing a circuit model 1300 of capacitive isolation circuit 208 (or a capacitive isolation channel) coupled to a differential transmitter and a differential receiver, and an equivalent circuit model representing a transfer function of common mode excitation applied across the isolation barrier to common mode transients at the transmitter or receiver 1320, respectively, in accordance with some examples. For simplicity, capacitive isolation circuit 208 is terminated on resistive impedances, different on both sides of capacitive isolation circuit 208, usually lower on the transmitter (TX) side and higher on the receiver (RX) side. Circuit model 1300 can represent, for example, the capacitive isolation structure provided by capacitors 1112 and 1122 of FIG. 11.

Here, the differential TX is modeled by resistors R1 and R3, where R1 is coupled between terminal 1301 and ground 1302, and R3 is coupled between ground 1302 and terminal 1303. The differential RX is modeled by resistors R2 and R4, where R2 is coupled between terminal 1304 and ground 1305 and R4 is coupled between ground 1305 and terminal 1306. In at least one example, resistances or impedances R1 and R3 are higher than resistances or impedances R2 and R4. Capacitive isolation circuit 208 is modeled by capacitors C1 and C2, where capacitor C1 is coupled to nodes 1301 and 1304 while capacitor C2 is coupled to node 1303 and 1306.

A differential signal is input from a transmitter to terminals 1301 and 1303, where the differential signal is differential relative to ground on terminal 1302. An output differential signal is received at terminals 1304 and 1306, and this output differential signal is differential relative to ground 1305. Here, a differential signal current 1307 from a transmitter flows from terminal 1301 to terminal 1304 via capacitor C1, and then back to terminal 1303 via resistors R2 and R4 and capacitor C2.

FIGS. 13C-D are schematics showing a circuit model 1330 of inductive isolation circuit 228 coupled to the differential transmitter and the differential receiver, and an equivalent circuit model representing a transfer function of a common mode excitation applied across the isolation barrier to common mode transients at the transmitter or receiver 1340, respectively, in accordance with some examples. Inductive isolation circuit 228 is modeled by a primary winding (e.g., windings 306) including inductors/coil portions L1 and L2, and a secondary winding (e.g., windings 308) including inductors/coil portions L3 and L4. Inductor L1 and resistor R1 are coupled in parallel between terminal 1331 and a grounded center tap 1332. Inductor L2 and resistor R2 are coupled in parallel between center tap 1332 and terminal 1333. Inductor L3 and resistor R3 are coupled in parallel between terminal 1334 and center tap 1335. Inductor L4 and resistor R4 are coupled in parallel between center tap 1335 and terminal 1336.

A differential signal is input from a transmitter to terminals 1331 and 1333, where the differential signal is differential relative to center tap 1332. An output differential signal is received at terminals 1334 and 1336, and this output differential signal is differential relative to center tap 1335. Here, the current 1338 from a transmitter flows from terminal 1331 to terminal 1334 via inductors L1 and L2. An electromagnetic field generated by current through inductors L1 and L2 is coupled through magnetic coupling to inductors L3 and L4. A corresponding current 1339 flows through inductors L3 and L4 to develop voltages on terminals 1334 and 1336 which are differential relative to ground on terminal 1335.

The common mode injection happens when the voltages on the isolated grounds (on nodes 1302 and 1305 for circuit model 1300, and on nodes 1332 and 1335 for circuit model 1330) move with respect to each other. The common mode injection or excitation moves the output differential signal on taps 1304 and 1306 relative to ground 1305 when compared with input differential signal on taps 1301 and 1303 relative to ground 1302. Such common mode injection may happen at low frequencies (e.g., 100 MHz or less). Common mode injection may cause inefficiencies in a DC-DC converter. For example, an enable signal may be transmitted by a bridge driver in data circuit 216 to a bridge receiver in data circuit 226 through capacitive isolation circuit 208 to turn on or off one or more N secondary side bridges 222. The voltage of this enable signal may shift up or down at capacitive isolation circuit 208 due to common mode injection. This shift in the enable signal may cause noise on a switching node of one or more N secondary side bridges 222, which in turn may reduce efficiency of the DC-DC converter formed by N primary side bridges 214, N transformers 206, and N secondary side bridges 222. Inductive isolation circuit 228 reduces common mode injection and so improves efficiency of the DC-DC converter, in at least one example.

Here, AC source 1307 indicates the disturbance in signal transfer caused by, for example, common mode injection or excitation. Upon exciting an AC source 1307 for circuit model 1300, voltages on nodes 1301, 1302, 1303, 1304, 1305, and 1306 move by common mode. Likewise, upon exciting the AC source 1307 for circuit model 1330, voltages on nodes 1331, 1332, 1333, 1334, 1335, and 1336 move by common mode. This means that circuit models 1300 and 1330 can be redrawn as equivalent circuit models 1320 and 1340, respectively, assuming the two half circuits of the differential channel are identical.

In at least one example, equivalent circuit model 1320 representing a capacitive isolation structure has a resistive divider between resistors R5 and R6 once the capacitor C3 is small enough in impedance. In at least one example, equivalent circuit model 1340 has a capacitor C3 in series, which is the parasitic capacitance across transformer of inductive isolation circuit 228. In inductive isolation circuit 228, resistors R5 and R6 of equivalent circuit model 1320 are replaced by the parallel of a resistor R5 and an inductor L5, and the parallel of resistor R6 and inductor L6. The disturbance contributed by AC source 1307 across resistor R6 (represented by A1) represents the AC common mode transient between nodes 1304 and 1306 (or between nodes 1301 and 1303). The magnitude of A1 can be based on a divider ratio between impedances of R6 and sum of impedances of R5, C3 and R6, which can be a constant with respect to signal frequency. This is true when R5 has a much smaller resistance than R6 and C3 has a low impedance in the frequency range considered, for example.

On the other hand, the equivalent circuit model 1340 representing the transformer includes a divider between a first parallel circuit of resistor R5 and inductor L5 and C3 in series with a second parallel circuit of resistor R6 and inductor L6. The disturbance contributed by AC source 1307 across resistor R6 and inductor L6 (represented by A2) represents the common mode transient between terminals 1334 and 1336 (or between terminals 1331 and 1333). The magnitude of A2 can be based on a divider ratio between the combined impedance of R6 and L6 and a sum of the combined impedance of R5 and L5 and the combined impedance of R6 and L6 in series with C3. When R5 has a much smaller resistance than R6 and C3 has a low impedance in the frequency range considered, L6 in parallel with R6 reduces the magnitude of A2, which can become smaller than A1, improving the common mode transient immunity.

FIG. 13E is a plot 1350 showing amplitudes of A1 (graph 1351) and A2 (graph 1352) as a function of frequency at the differential receiver coupled to capacitive isolation circuit 208 and inductive isolation circuit 228, in accordance with at least one example. At lower frequencies, the inductors L5 and L6 behave as short circuits and so the impedance of the inductors becomes much smaller than the impedance of the resistor. Therefore, at lower frequencies the amplitude of A2 for circuit model 1340 is low as indicated by graph 1352. At higher operating frequencies, the gain A2 increases, which also increases the disturbance on terminals 1334 and 1336. In contrast, the gain A1 for equivalent circuit model 1320 is relatively flat and high at lower frequencies since it does not have inductors as indicated by graph 1351. In at least one example, inductive isolation circuit 228 has better common mode rejection and thus less disturbance at lower operating frequencies (e.g., 100 MHz or less) compared to capacitive isolation circuit 208.

In addition to improved common mode transient immunity, a transformer can provide additional advantages over capacitors for galvanic isolation. Specifically, at least compared with a case where the capacitors are implemented in the metallization layer over the semiconductor die, the vertical spacing between the transformer and the semiconductor die can be increased due to the relatively large package substrate thickness, which can reduce parasitic capacitance. The eddy current caused by magnetization of the semiconductor die by the transformer can also be reduced. Second, matching capacitors is challenging because to match the capacitors, physical dimensions of the capacitors are to be matched while transformer matching is achieved by shifting the center tap of the transformer. Accordingly, the transformer can provide improved matching over capacitors.

FIG. 14 is a schematic of a data portion 1400 of a packaged IC comprising data circuits 216 and 226 and their respective inductive isolation (e.g., transformer) circuits 228a and 228b, in accordance with at least one example. Here, two differential signal paths are coupled to inductive isolation circuits 228a and 228b to allow for bidirectional data communication. In at least one example, data circuit 216 includes transmitter 1417a and receiver 1417b, where transmitter 1417a includes a resonant LC oscillator with startup mechanism (not shown) and receiver 1417b includes radio frequency detector with common mode (CM) rejection. In at least one example, data circuit 226 includes receiver 1426a and transmitter 1426b, where transmitter 1426b includes a resonant LC oscillator with startup mechanism (not shown) and receiver 1426a includes radio frequency detector with common mode (CM) rejection. In at least one example, receiver 1426a receives differential signal transmitted by transmitter 1417a through inductive isolation circuit 228a. In at least one example, receiver 1417b receives differential signal transmitted by transmitter 1426b through inductive isolation circuit 228b.

In some examples, as to be shown in FIGS. 15-23, inductive isolation circuit 228a comprises a primary winding having a first coil portion L1a and a second coil portion L2a, and a secondary winding having a third coil portion L3a and a fourth coil portion L4a. Here “primary” and “secondary” are to connote two different isolation domains (e.g., two power domains) that are galvanically isolated by the isolation circuit. Power/data can flow from primary side to secondary side and vice versa. In some examples, all primary windings are coupled to a first power domain, and all secondary windings are coupled to a second power domain. In some examples, different primary windings can be coupled to different first power domains, and different secondary windings can be coupled to different second power domains.

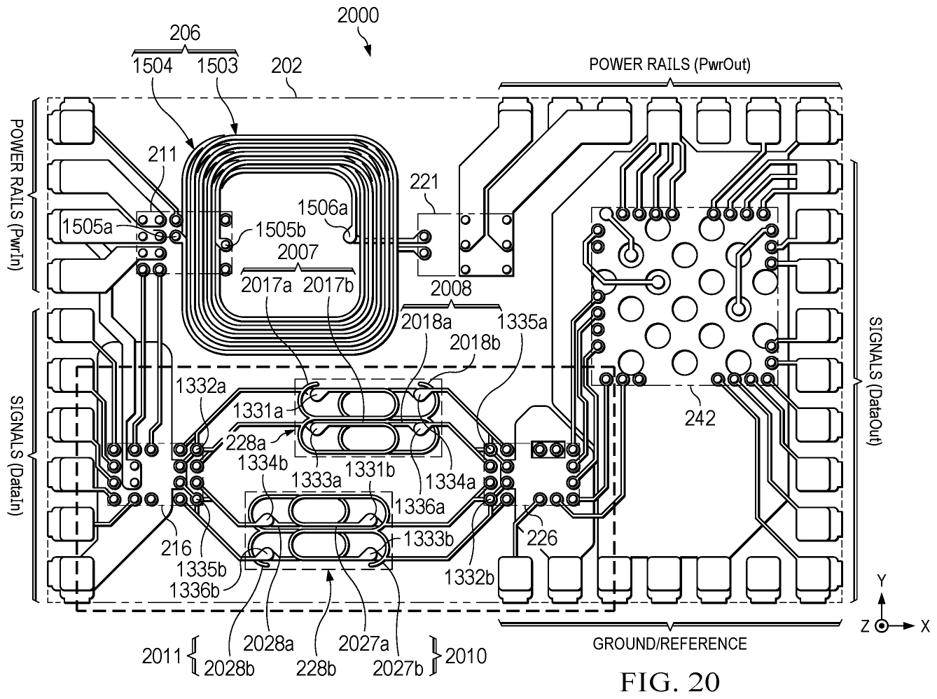

In FIGS. 15-19, L1a and L2a are coupled in series in a figure-of-8 configuration. In FIGS. 20-23, L1a and L2a are coupled in series in another configuration. Each of first coil portion L1a and second coil portion L2a extends from a center tap 1332a having a node shape (e.g., oval, circle, polygon, etc.) and terminates at, respectively, first primary side terminal 1331a and second primary side terminal 1333a, which are at the respective center of first coil portion L1a and second coil portion L2a. A center tap 1332a is a tap located between the first coil portion L1a and the second coil portion L2a, and is coupled to a first local ground associated with data circuit 216. By placing center tap 1332a in the center of the figure-of-8 configuration, symmetry can be achieved between the two coils of the first coil portion L1a. Loss in symmetry caused by an offset in the location of center tap 1332a relative to the coil portions of the first coil portion L1a may reduce signal-to-noise ratio. In at least one example, first primary terminal 1331a is coupled to a first output terminal of transmitter 1417a and second primary terminal 1333a is coupled to a second output terminal of transmitter 1417a. Here, capacitors C_{DIFF} is the differential tuning capacitance between the first and second output terminals of transmitter 1417a, while capacitors C_{TX} are common mode tuning capacitances between first primary side terminal 1331a and the first local ground (coupled to center tap 1332a), and between second primary side terminal 1333a and the first local ground. Both C_{DIFF} and C_{TX} can be implemented with lumped circuit elements or leveraging parasitics or a combination of both.

In some examples, as to be shown in FIGS. 15-23, inductive isolation circuit 228a comprises a secondary winding having a first coil portion L3a and a second coil portion L4a. In FIGS. 15-19, L3a and L4a are coupled in series in a figure-of-8 configuration. In FIGS. 20-23, L3a and L4a are coupled in series in another configuration. Each of first coil portion L3a and second coil portion L4a extends from a center tap 1335a having a node shape and terminates at, respectively, first secondary side terminal 1334a and second secondary side terminal 1336a, which are at the respective centers of first coil portion L3a and second coil portion L4a. The secondary winding is in a different layer of a substrate than the primary winding, and may overlap at least partially with the primary winding. Center tap 1335a is coupled between first coil portion L3a and second coil portion L4a, and is also coupled to a second local ground associated with data circuit 226. In at least one example, first secondary side terminal 1334a is coupled to a first input terminal of receiver 1426a while second secondary side terminal 1336a is coupled to a second input terminal of receiver 1426a. Here, capacitors C_{DIFF} is the differential tuning capacitance between the first and second input terminals of receiver 1426a, while capacitors C_{RX} are common mode tuning capacitance between first secondary side terminal 1334a and the second local ground (coupled to center tap 1335a), and between the second secondary side terminal 1336a and the first local ground. Both C_{DIFF} and C_{TX} can be implemented with lumped circuit elements or leveraging parasitics or a combination of both.

In some examples, as to be shown in FIGS. 15-23, inductive isolation circuit 228b comprises a secondary winding having a first coil portion L1b and a second coil portion L2b, which can be coupled in series in a figure-of-8 configuration as shown in FIGS. 15-19 or in other configurations as shown in FIGS. 20-23. The secondary winding of inductive isolation circuit 228b can be coupled to a same second power domain, or a different power domain, as the secondary winding of inductive isolation circuit 228a. Each of first coil portion L1b and second coil portion L2b extends from a center tap 1332b having a node shape and terminates at, respectively, first secondary side terminal 1331b and second secondary side terminal 1333b, which are at the respective center of first coil portion L1b and second coil portion L2b. Center tap 1332b is coupled between the first coil portion L1b and the second coil portion L2b and is also coupled to a first local ground associated with data circuit 226. In at least one example, first secondary side terminal 1331b is coupled to the first input terminal of transmitter 1426b while second secondary side terminal 1333b is coupled to a second input terminal of transmitter 1426b. Here, capacitor C_{DIFF} is the differential tuning capacitance between the first and second input terminals of receiver 1417b, while capacitors C_{RX} are the common mode tuning capacitance between first primary side terminal 1334b and the first local ground (coupled to center tap 1335b), and between the second primary side terminal 1336b and the first local ground of date circuit 216. Both C_{DIFF} and C_{RX} can be implemented with lumped circuit elements or leveraging parasitics or a combination of both.

In some examples, as to be shown in FIGS. 15-23, inductive isolation circuit 228b comprises a primary side winding having a first coil portion L3b and a second coil portion L4b, which can be coupled in series in a figure-of-8 configuration as shown in FIGS. 15-19 or in other configurations as shown in FIGS. 20-23. The primary winding of inductive isolation circuit 228b can be coupled to the same first power domain, or a different power domain, as the primary winding of inductive isolation circuit 228a. Each of first coil portion L3b and second coil portion L4b extends from a center tap 1335b having a node shape and terminates at, respectively, first primary side terminal 1334b and second primary side terminal 1336b, which are at the respective centers of first coil portion L3b and second coil portion L4b. Center tap 1335b is coupled between the first coil portion L3b and the second coil portion L4b, and is coupled to the first local ground associated with data circuit 216. In at least one example, first primary terminal 1334b is coupled to a first output terminal of transmitter 1426b while second primary terminal 1336b is coupled to a second output terminal of transmitter 1426b. Here, capacitor C_{DIFF} is the common mode tuning capacitance between the first and second input terminals of transmitter 1426b, while capacitors C_{TX} are the common mode tuning capacitance between first secondary side terminal 1331b and the second local ground (coupled to center tap 1332b), and between the second primary side terminal 1333b and second first local ground of data circuit 226. Both C_{DIFF} and C_{TX} can be implemented with lumped circuit elements or leveraging parasitics or a combination of both.

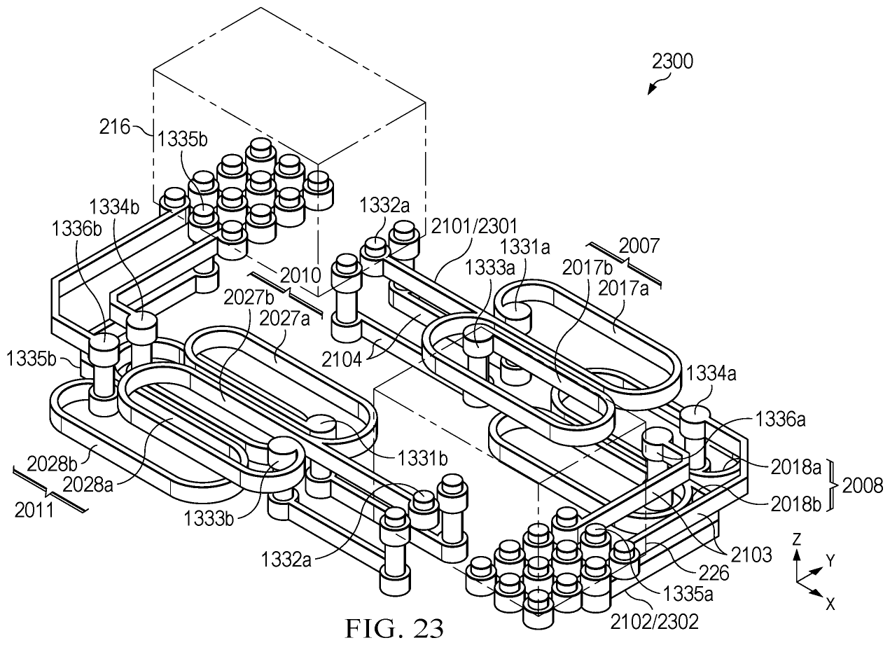

In at least one example, as to be shown in FIGS. 20-23, an inductive isolation circuit can include an elongated metal interconnect that extends laterally from a center tap outside the footprint of the inductive isolation circuit, and a first coil portion and a second coil portion that collectively form a primary or secondary winding are coupled to the metal interconnect, so that the metal interconnect is coupled to the primary/secondary winding in at least two locations. The metal interconnect can include a matched/balanced branch portion (e.g., as shown in FIGS. 20-22) or in the form of a line (e.g., as shown in FIG. 23). For example, inductive isolation circuit 228a can include a first metal interconnect coupled between center tap 1332a and first coil portion L1a and between center tap 1332a and second coil portion L2a. Inductive isolation circuit 228a can also include a second metal interconnect coupled between center tap 1335a and first coil portion L3a and between center tap 1335a and second coil portion L4a. Also, inductive isolation circuit 228b can include a third metal interconnect coupled between center tap 1332b and first coil portion L1b and between center tap 1332b and second coil portion L2b. Inductive isolation circuit 228b can also include a fourth metal interconnect coupled between center tap 1335b and first coil portion L3b and between center tap 1335b and second coil portion L4b. As to be explained below, such arrangements can improve the matching of the differential signals. Also, the coils and the metal interconnects in such arrangements can be implemented in two metal layers. Reducing the number of metal layers allows thicker metal layers to be used while increasing the vertical separation between metal layers, which can reduce parasitic capacitance and crosstalk between metal layers.

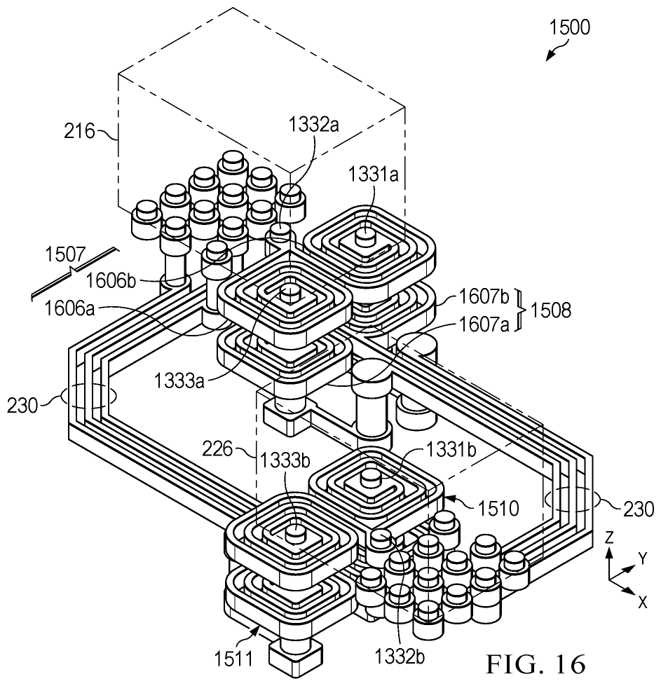

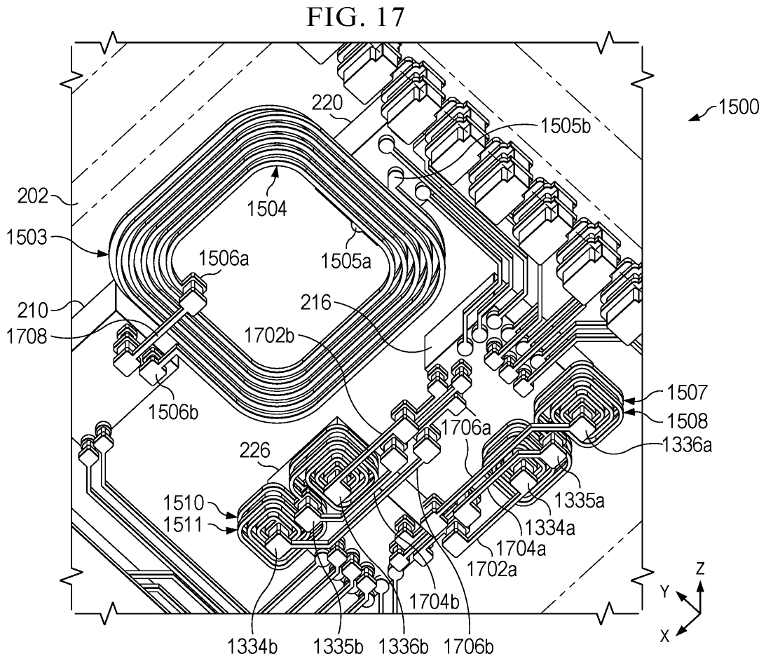

FIG. 15 is a schematic showing a top view of a packaged IC 1500 with separate power and data semiconductor dies, three transformers, and application specific semiconductor die 242, in accordance with at least one example. FIG. 16 is a schematic showing an isometric top view of packaged IC 1500 having data transformers under data semiconductor dies, in accordance with at least one example. FIG. 17 is a schematic showing an isometric bottom view of packaged IC 1500 having the three transformers, in accordance with at least one example.

Packaged IC 1500 can be an example of the packaged IC of FIG. 2D. Packaged IC 1500 can also be an example of FIGS. 2B-C. Here, N transformer 206 comprises a first primary winding 1503 in a first metal layer and a first secondary winding 1504 in a second metal layer, where the second metal layer is below the first metal layer (e.g., the topmost metal layer) of package substrate 202. In this example, first primary winding 1503 and first secondary winding 1504 are concentric windings that substantially overlap each other within package substrate 202 for higher inductive coupling.

As described with reference to FIG. 2D, isolation circuit 204 which includes N transformer 206 (e.g., a first transformer) is embedded or integrated in package substrate 202. In at least one example, package substrate 202 includes three metal layers, which provides flexibility in fabricating concentric windings (first primary winding 1503 and first secondary winding 1504) in two different layers for first transformer 206 to achieve higher magnetic coupling between the primary and secondary coils of first transformer 206. The package substrate also allows for integrating metal pillars between the windings and the flip-chip mounted semiconductor dies (e.g., first semiconductor die 210 and second semiconductor die 220) above them. While semiconductor dies (e.g., first semiconductor die 210 and second semiconductor die 220) in at least one example may be connected to first transformer 206 underneath them via wire bonding, such wire bonding may cause additional inductance that may couple to first transformer 206 and cause disturbance in the isolation function of first transformer 206.

In at least one example, first transformer 206 includes a first primary side terminal 1505a, a second primary side terminal 1505b, a first secondary side terminal 1506a, and a second secondary side terminal 1506b (shown in FIG. 17). First primary side terminal 1505a and a second primary side terminal 1505b are the two ends of first primary winding 1503. First secondary side terminal 1506a and second secondary side terminal 1506b are the two ends of first secondary winding 1504. In at least one example, first primary winding 1503 is on a first metal layer (e.g., top metal layer 328) and second primary winding 1504 is on second metal layer (e.g., metal layer 322) below the first metal layer.

In at least one example, first semiconductor die 210 is coupled to first primary side terminal 1505a and second primary side terminal 1505b. Here, first primary side terminal 1505a and second primary side terminal 1505b are under first semiconductor die 210 and on the topmost layer of package substrate 202 which allows connecting of first primary side terminal 1505a and second primary side terminal 1505b to a die above them through metal pillars. As such, routing distances are reduced and the use of intermediate interconnects between first primary side terminal 1505a and first semiconductor die 210, and between second primary side terminal 1505b and first semiconductor die 210 may be avoided. Metal pillars (e.g., copper pillar or posts) extend vertically (in the z-direction) directly from package substrate 202 to first semiconductor die 210 or couple to a solder ball of first semiconductor die 210.

In at least one example, second semiconductor die 220 is coupled to first secondary side terminal 1506a and second secondary side terminal 1506b. In at least one example, as shown in FIG. 15, second semiconductor die 220 does not overlap transformer 206. In at least one example, semiconductor die 220 may also overlap transformer 206. In at least one example, first secondary side terminal 1506a and second secondary side terminal 1506b are in a metal layer below the topmost metal layer of package substrate 202, and so intermediate metal interconnects and vias or pillars are used to connect to second semiconductor die 220 on package substrate 202.

In at least one example, when first semiconductor die 210 is not directly above first primary side terminal 1505a and second primary side terminal 1505b, first metal interconnect 1512 (similar to interconnect 361) is coupled between first primary side terminal 1505a of first primary winding 1503 and first semiconductor die 210. In at least one example, third metal interconnect 1513 (similar to interconnect 363) is coupled between second primary side terminal 1505b of first primary winding 1503 and first semiconductor die 210. In at least one example, second metal interconnect 362 is coupled between first secondary side terminal 1506a of first secondary winding 1504 and second semiconductor die 220. In at least one example, fourth metal interconnect 364 is coupled between second secondary side terminal 1506b of first secondary winding 1504 and second semiconductor die 220.

First primary winding 1503 and first secondary winding 1504 are electrically and galvanically isolated from each other using an isolation material (e.g., isolation material 314 or isolation material 1014) of package substrate 202, which forms a galvanic isolation barrier between two different power domains of first semiconductor die 210 and second semiconductor die 220. In at least one example, first semiconductor die 210 is powered using a voltage supply and ground connection associated with a first power domain. In at least one example, second semiconductor die 220 is powered using a different voltage supply and ground connection associated with a second power domain. In at least one example, the isolation material, e.g., the mold compound, has a thickness and is a type that provides a galvanic isolation barrier that withstands 5 kilovolts (kV) root mean square (RMS) for 60 seconds in one example and 2.5 kV RMS for 60 seconds in another example. Different isolation ratings may be achievable based at least in part on the type and thickness of the isolation material used.

Using a mold compound as the isolation material, instead of a laminate, allows for a smaller critical separation between first primary winding 1503 and first secondary winding 1504 while maintaining the same voltage insulation and allows for improved thermal performance of isolation circuit 204. In at least one example, routable lead frame technology for package substrate 202 allows for thicker copper traces (e.g., 30-35 micrometers or thicker, for instance 1%, 5%, or 10% thicker) and smaller metal width and spacing (e.g., 30×30 micrometers² or less, for instance 1%, 5%, or 10% less). This may lead to an improved efficiency of transformer 206 by allowing an increased quality factor for transformer 206. Also, integrating transformer 206 into package substrate 202 allows for smaller packaged IC sizes (e.g., 5.0×3.0×0.8 millimeters³ or less, for instance 1%, 5%, or 10% less).

In at least one example, isolation circuit 204 includes inductive isolation circuit 228 having a set of transformers including second transformer 228a which comprises a second primary winding 1507 and a second secondary winding 1508, both having a figure-of-8 configuration. In at least one example, second primary winding 1507 and second secondary winding 1508 are concentric windings that substantially overlap each other within package substrate 202 for higher inductive coupling. In at least one example, second secondary winding 1508 is under second primary winding 1507 and occupies same footprint as second primary winding 1507. Second primary winding 1507 and second secondary winding 1508 provide data isolation between data transmitter 1417a and data receiver 1426a.

In at least one example, second transformer 228a of inductive isolation circuit 228 includes first primary side terminal 1331a, second primary side terminal 1333a, first secondary side terminal 1334a, and second secondary side terminal 1336a. In at least one example, second primary winding 1507 is coupled between first primary side terminal 1331a and second primary side terminal 1333a, and the second secondary winding 1508 is coupled between the first secondary side terminal 1334a and the second secondary side terminal 1336a. In at least one example, metal pillars extend vertically from first primary side terminal 1331a, center tap 1332a, and second primary side terminal 1333a to receiver 1426a above it to reduce parasitic capacitance and inductance caused by wire bonding. As shown, at least a portion of windings of second transformer 228a overlaps data circuit 216 to allow the metal pillars to connect to receiver 1426a. In this example, second transformer 228a is outside a footprint of (or otherwise not surrounded by) first transformer 206, which allows the metal interconnects coupled between transformer 228a and data circuit 216 to also stay out of first transformer 206, which can reduce the number of metal layers for implementing transformers 206 and 228a and the metal interconnects.

Having transformers 228a and 228b outside the footprint of transformer 206 allows to reduce the crosstalk between the signals of the three transformers. In the example of transformer 206 providing power transfer, transformer 206 can generate a common mode magnetic field that passes through transformers 228a and 228b when transferring power. Although the transformers 228a and 228b operate using two figure-8 coils which have a differential field and can be robust to a common mode variation of the magnetic field, such common mode variation may still perturb the TX and RX operating points. By moving transformers 228a and 228b outside the footprint of transformer 206, the common mode magnetic field received by transformers 228a and 228b can become much weaker, which can further reduce the perturbance of the TX and RX operating points by the common mode variation. Such arrangements can also further separate transformer 206 from the metal layers of transformers 228a and 228b, which can reduce the parasitic capacitance of transformer 206 and increase its quality factor.

In at least one example, packaged IC 1500 includes data circuit 216 (e.g., a third semiconductor die) and data circuit 226 (e.g., a fourth semiconductor die). Data circuit 216 is coupled to first primary side terminal 1331a and second primary side terminal 1333a. Data circuit 226 is coupled to first secondary side terminal 1334a and second secondary side terminal 1336a. Data can be transmitted from data circuit 216 via second transformer 228a to data circuit 226.

Referring to FIGS. 16 and 17, for package substrate 202 including three metal layers, first primary side terminal 1331a, second primary side terminal 1333a, first center tap 1332a, and second primary winding 1507 of second transformer 228a can be formed in a first (e.g., top) metal layer and coupled to data circuit 226 via metal pillars. Second secondary winding 1508 of second transformer 228a can be formed in a second (e.g., middle) metal layer. First secondary side terminal 1334a, second secondary side terminal 1336a, and second center tap 1335a can be formed in third (e.g., bottom) metal layer and can be coupled to second secondary winding 1508 by metal vias. The third metal layer also includes metal interconnects 1702a, 1704a, and 1706a coupled between data circuit 216 and first secondary side terminal 1334a, second center tap 1335a, and second secondary side terminal 1336a, respectively. In at least one example, a metal interconnect 1708 is coupled between second semiconductor die 210 and first secondary side terminal 1506a.

Also, first primary winding 1503, first primary side terminal 1505a, and second primary side terminal 1505b of transformer 206 are in the first metal layer, first secondary winding 1504. Also, first secondary side terminal 1506a, and second secondary side terminal 1506b of transformer 206 are in the second metal layer. Second secondary side terminal 1506b is coupled to second semiconductor die 210 via metal pillars. In at least one example, third metal layer also includes a metal interconnects 1708 coupled between first secondary side terminal 1506a and second semiconductor die 210.

In at least one example, transformer 228 also includes a third transformer 228b including a third secondary winding 1510 and a third primary winding 1511. In at least one example, third secondary winding 1510 and third primary winding 1511 are concentric windings that substantially overlap each other within package substrate 202 for higher inductive coupling. In at least one example, third secondary winding 1510 is coupled between first secondary side terminal 1331b and second secondary side terminal 1333b. In at least one example, third primary winding 1511 is coupled between first primary side terminal 1334b and second primary side terminal 1336b. The third metal layer also includes metal interconnects 1702b, 1704b, and 1706b coupled between data circuit 226 and second primary side terminal 1336b, second center tap 1335b, and first primary side terminal 1334b, respectively.

In at least one example, metal pillars extend directly from first primary side terminal 1331a, center tap 1332a, and second primary side terminal 1333a to transmitter 1417a above it to reduce parasitic capacitance and inductance caused by wire bonding. As shown, at least a portion of coils of third transformer 228a overlaps data circuit 216 to allow the metal pillars to connect to transmitter 1417a. In at least one example, metal pillars extend directly from first secondary side terminal 1331b, center tap 1332b, and second secondary side terminal 1333b to transmitter 1426b above it to reduce parasitic capacitance and inductance caused by wire bonding. As shown, at least a portion of coils of third transformer 228b overlaps data circuit 226 to allow the metal pillars to connect to transmitter 1426b.

Referring to FIGS. 16 and 17, in at least one example, second primary winding 1507 includes a first coil portion 1606a, a second coil portion 1606b, and first center tap 1332a coupled between first coil portion 1606a and second coil portion 1606b. Each of first coil portion 1606a and second coil portion 1606b extends from center tap 1332a and terminates at, respectively, first primary side terminal 1331a and second primary side terminal 1333a, which are at the respective center of first coil portion 1606a and second coil portion 1606b. In at least one example, first coil portion 1606a and second coil portion 1606b can have a same turn direction.

In at least one example, second secondary winding 1508 includes a first coil portion 1607a, a second coil portion 1607b, and second center tap 1335a coupled between first coil portion 1607a and second coil portion 1607b. Each of first coil portion 1607a and second coil portion 1607b extends from center tap 1335a and terminates at, respectively, first secondary side terminal 1334a and second secondary side terminal 1333a, which are at the respective center of first coil portion 1607a and second coil portion 1607b. In at least one example, first coil portion 1607a and second coil portion 1607b can have the same turn direction.

In at least one example, each of first semiconductor die 210 and second semiconductor die 220 includes respective half-bridge circuits. In at least one example, each of data circuit 216 and data circuit 226 include respective data transmit and data receive circuits. In at least one example, packaged IC 1500 includes a fifth semiconductor die 242 having power terminals and data terminals. The power terminals are coupled to the second semiconductor die 220 while the data terminals are coupled to data circuit 226 (e.g., the fourth semiconductor die). As discussed herein, first semiconductor die 210, first transformer 206, and second semiconductor die 220 are part of an isolated power converter (e.g., DC-DC converter).

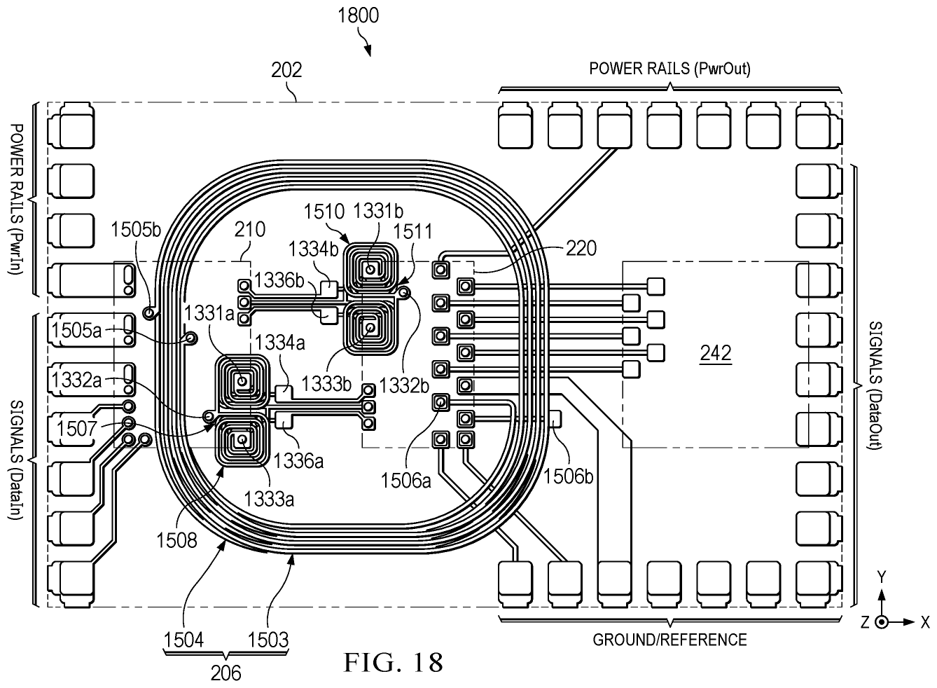

FIG. 18 is a schematic showing an isometric top view of packaged IC 1800 where data transformers are within a footprint of (or surrounded by) a power transformer, in accordance with at least one example. In at least one example, second transformer 228a and third transformer 228b are within a footprint of first transformer 206. In at least one example, first transformer 206 includes first primary winding 1503 formed in a topmost layer of package substrate 202, and first secondary winding 1504 below first primary winding 1503. First primary winding 1503 is like first primary winding 1503 in feature and function, and may be larger in size so that second transformers 228a and 228b can fit within the footprint of first transformer 206.

In at least one example, second semiconductor die 220 is positioned within the footprint of first transformer 228. In at least one example, data circuit 216 and data circuit 226 are part of first semiconductor die 210 and second semiconductor die 220, respectively. In at least one example, first semiconductor die 210 overlaps and is coupled to first primary winding 1503, second primary winding 1507, and third primary winding 1511 (not shown in FIG. 18). Second semiconductor die 220 is coupled to first secondary winding 1504, second secondary winding 1508 (not shown in FIG. 18), and third secondary winding 1510. In at least one example, second transformer 228a comprising second primary winding 1507 and second secondary winding 1508 also overlaps first semiconductor die 210. Coupling of second transformer 228a and third transformer 228b with their respective first semiconductor die 210 and second semiconductor die 220 is similar as discussed with reference to FIGS. 15-17. In the example of FIG. 18, first semiconductor die 210 and second semiconductor die 220 can form an isolated DC-DC converter using first transformer 206 to transmit power, and use second and third transformers 228a and 228b to send control signals (e.g., feedback voltage) to support output current and voltage regulations. First semiconductor die 210 and second semiconductor die 220 can also use second and third transformers 228a and 228b to send data in and out of semiconductor die 242, where data signals and control signals are interleaved/multiplexed, as described in U.S. patent application Ser. No. 17/363,470, which is incorporated by reference.

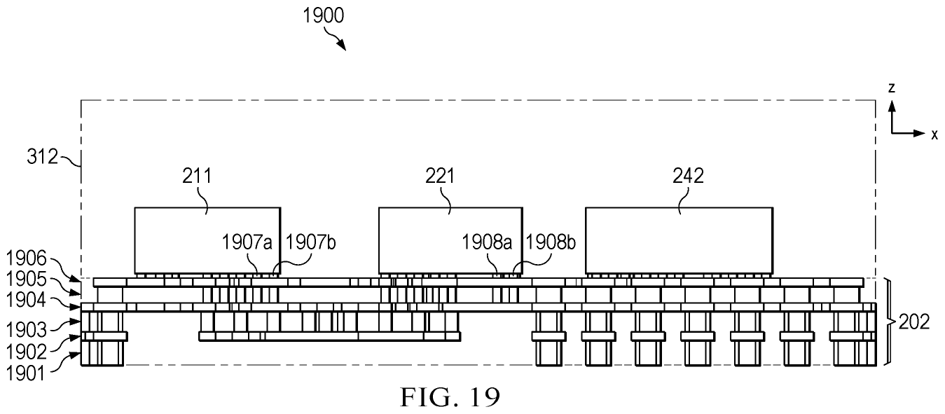

FIG. 19 is a schematic showing a cross-sectional view of packaged IC 1900 (an example of packaged IC 1500) having a package substrate with three metal layers, in accordance with at least one example. Packaged IC 1900 is similar in function and feature of cross-section of packaged IC 300 of FIG. 5. Here, three layers are shown with vias between the layers. These layers and vias from the bottom up include via1 1901, layer 1 1902, via2 1903, layer 2 1904, via3 1905, layer 3 1906 (topmost layer of package substrate 202). Vial is used to connect package substrate 202 to a printed circuit board. In at least one example, transformer 206 is formed on layer 3 1906 and layer 2 1904, where primary winding 1503 is on layer 3 1906 while secondary winding 1504 is on layer 2 1904.

In at least one example, packaged IC 1900 includes a first metal pillar 1907a coupled between first metal interconnect 361 and first semiconductor die 210, a second metal pillar 1907b coupled between third metal interconnect 363 and first semiconductor die 210. In at least one example, packaged IC 1900 includes a third metal pillar 1908a coupled between second metal interconnect 362 and second semiconductor die 220, and a fourth metal pillar 1908b coupled between fourth metal interconnect 364 and second semiconductor die 220. These metal pillars 1907a, 1907b, 1908a, and 1908b can be made of copper (e.g., copper-to-copper pillars) or any other suitable material. Metal pillars 1907a, 1907b, 1908a, and 1908b allow first semiconductor die 210 and/or second semiconductor die 226 to partially overlap transformer 206. Such overlapping reduces the overall size of packaged IC 1900 in the x-y direction.

In at least one example, second primary winding 1507 is in first metal layer 1906 (e.g., the topmost layer of package substrate 202) and is coupled to one of first semiconductor die 210 or data circuit 216 (e.g., a third semiconductor die) that overlaps with second primary winding 1507. In at least one example, second secondary winding 1508 is in second metal layer 1904 below the first metal layer 1906. In at least one example, third metal layer 1902 includes metal interconnects coupled between second secondary winding 1508 and one of second semiconductor die 220 or data circuit 226 (e.g., fourth semiconductor die).

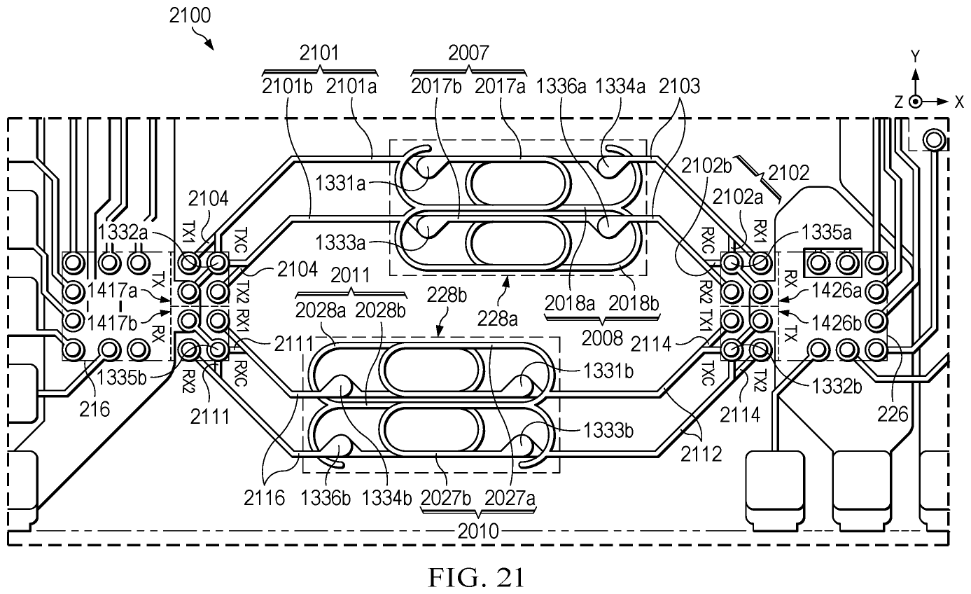

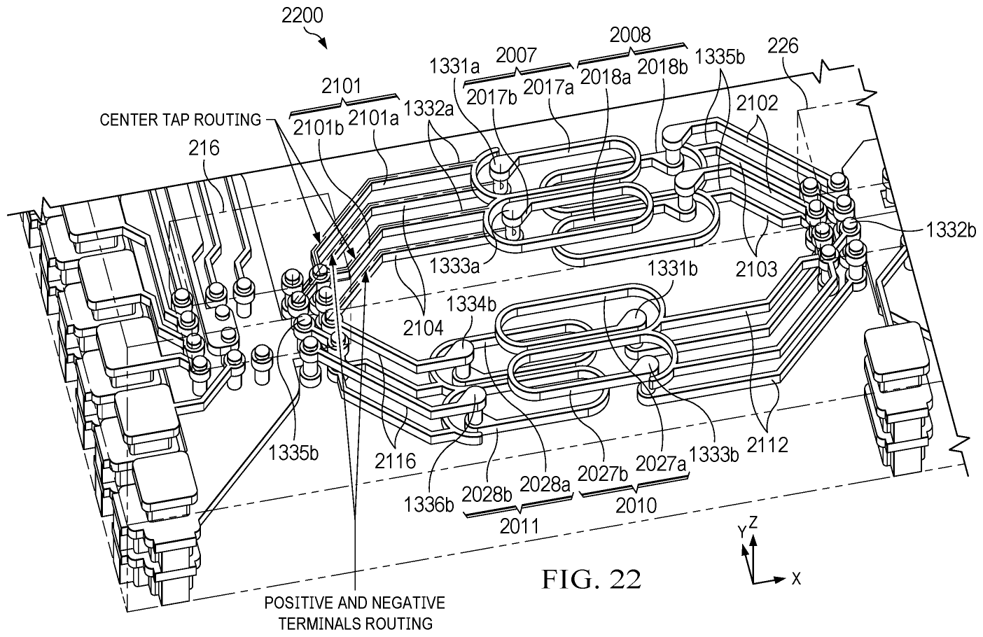

FIG. 20 is a schematic showing an isometric top view of a packaged IC 2000 with partially overlapping primary and secondary windings of the data transformers, in accordance with at least one example. FIG. 21 is a schematic showing a top zoomed-in top view of packaged IC 2000 referred to as packaged IC 2100 with the partially overlapping primary and secondary windings of the data transformers, in accordance with at least one example. FIG. 22 is a schematic showing an isometric view of a packaged IC 2200 (a portion of packaged IC 2000) with partially overlapping primary and secondary windings of the data transformers, in accordance with at least one example.

Packaged IC 2000 is similar in feature and function to packaged IC 1500. In at least one example, package substrate 202 can have three metal layers. In at least one example, to increase inductance of transformer 206, first primary winding 1503 may have more windings or turns in the first metal layer compared to first primary winding 1503 in packaged IC 1500. Likewise, first secondary winding 1504 is concentric to first primary winding 1503 but with more windings or turns, in accordance with at least one example. In at least one example, second transformer 228a and third transformer 228b have different winding patterns and overlapping ratio of their respective primary and secondary windings. In at least one example, transformer 228a includes a second primary winding 2007 and a second secondary winding 2008, which partially overlaps each other. Transformer 228b includes a third primary winding 2010 and a third secondary winding 2011, which also partially overlaps each other. In FIGS. 20-23 transformers 228a and 228b are outside the footprint of transformer 206. In some examples, transformers 228a and 228b can be within the footprint of transformer 206, as in FIG. 18.

The winding pattern and connection of taps in package IC 2000 for second transformer 228a and third transformer 228b are different from those in package IC 1500. As described below, the winding pattern and connection of taps of transformers 228a and 228b in FIGS. 20-24 can improve symmetry. For example, any asymmetry caused by metal interconnect routing of first secondary side terminal 1334a, center tap 1335a, and second secondary side terminal 1336a under second secondary winding 1508 to data circuit 226 are mitigated by the winding pattern and tap locations for second transformer 228a in FIG. 20. In at least one example, the same configuration is applied to third transformer 228b. By achieving more symmetry in routing of these taps, common mode rejection improves.

In at least one example, second primary winding 2007 is in one layer (e.g., topmost metal layer of package substrate 202) and second secondary winding 2008 is on a layer below the topmost metal layer. In at least one example, each of second primary winding 2007 and second secondary winding 2008 has two windings in a figure-of-8 configuration. The windings can have oval shapes (as shown in FIGS. 20-23), or other winding shapes such as circular shapes, rectangular shapes, square shapes, etc.

In at least one example, second primary winding 2007 has a first primary side terminal 1331a, a center tap 1332a, and a second primary side terminal 1333a. In FIGS. 20-23, the center taps of transformers 228a and 228b are positioned away from the footprints of transformers 228a and 228b. For example, referring to FIG. 21, center tap 1332a is positioned outside the footprint of transformer 228a and are coupled to second primary winding 2007 by a center tap metal interconnect 2101 that extends laterally between transformer 228a and center tap 1332a. In at least one example, the center tap metal interconnect can have matched/balanced branch portions 2101a and 2101b shown in FIGS. 21 and 22 or a straight portion of metal interconnect 2301 of FIG. 23. In at least one example, two coil portions 2017a and 2017b extend from the branch/straight portions forming second primary winding 2007, where coil portion 2017a terminates at first primary side terminal 1331a and coil portion 2017b terminates at second primary side terminal 1333a. First primary side terminal 1331a and second primary side terminal 1333a are coupled to data circuit 216 via a pair of metal interconnects 2104, which are formed in the second metal layer and under the center tap metal interconnect 2101. Symmetry/matching can be achieved by, for example, having the pair of metal interconnects 2104 overlapping with the branch portions 2101a and 2101b of the center tap metal interconnect 2101, as shown in FIG. 21, or having the pair of metal interconnects 2104 being equal distance from the straight portion of metal interconnect 2301. In both cases, the pair of metal interconnects 2104 can have matched capacitive loading, which can improve symmetry and matching between the differential signals on metal interconnects 2104.

In at least one example, center tap 1332a is formed under data circuit 216 and coupled to data circuit 216 through a metal pillar or post (e.g., copper pillar) while first primary terminal 1331a and second primary terminal 1333a are away from data circuit 216 because second primary winding 2007 is not overlapping data circuit 216.

In at least one example, second secondary winding 2008 has similar or exact topology as second primary winding 2007 with a portion (e.g., half) of it overlapping second secondary winding 2008. In at least one example, center tap 1335a is positioned outside the footprint of transformer 228a and are coupled to second secondary winding 2008 by a center tap metal interconnect 2102 that extends laterally between transformer 228a and center tap 1335a. In at least one example, the center tap metal interconnect can have balanced/matched branch portions 2102a and 2102b shown in FIGS. 21 and 22 or a straight portion of metal interconnect 2302 of FIG. 23. Two coil portions 2018a and 2018b extend from the branch/straight portions forming second secondary winding 2008, where coil portion 2018a terminates at first secondary side terminal 1334a and coil portion 2018b terminates at second primary side terminal 1336a. First secondary side terminal 1334a and second secondary side terminal 1336a are coupled to data circuit 226 via a pair of metal interconnects 2103, which are formed in the second metal layer and under the center tap metal interconnect 2102. Symmetry/matching can be achieved by, for example, having the pair of metal interconnects 2103 overlapping with the branch portions 2102a and 2102b of the center tap metal interconnect 2102, as shown in FIG. 21, or having the pair of metal interconnects 2103 being equal distance from the straight portion of metal interconnect 2302.

In at least one example, transformer 228b has similar or exact topology as transformer 228a. For example, center tap 1332b is positioned outside the footprint of transformer 228b and is coupled to third primary winding 2010 by a center tap metal interconnect 2112 that extends laterally between transformer 228b and center tap 1332b. Third primary winding 2010 includes coil portions 2027a and 2027b that terminate at, respectively, first secondary side terminals 1331b and second secondary side terminals 1333b. A pair of metal interconnects 2114 couples between data circuit 226 and first secondary side terminals 1331b and second secondary side terminals 1333b. Symmetry/matching can be achieved by having the pair of metal interconnects 2114 overlapping with the branch portions of metal interconnect 2112 or being equal distance from the straight portion of metal interconnect 2112.

Also, center tap 1335b is also positioned outside the footprint of transformer 228b and is coupled to third secondary winding 2011 by a center tap metal interconnect 2111. Third secondary winding 2010 includes coil portions 2028a and 2028b that terminate at, respectively, first primary side terminal 1334b and second primary side terminal 1336b. A pair of metal interconnects 2116 couples between data circuit 216 and first primary side terminals 1334b and second primary side terminals 1336b. Symmetry/matching can be achieved by having the pair of metal interconnects 2116 overlapping with the branch portions of metal interconnect 2111 or being equal distance from the straight portion of metal interconnect 2111.

In at least one example, second primary winding 2007 and second secondary winding 2008 are electrically and galvanically isolated using an isolation material (e.g., isolation material 314 or isolation material 1014) of package substrate 202, which forms a galvanic isolation barrier between two different power/data domains of data circuit 216 and data circuit 226. In at least one example, data circuit 216 is powered using a voltage supply and ground connection associated with a first power domain. In at least one example, data circuit 226 is powered using a different voltage supply and ground connection associated with a second power domain.

Using a mold compound as the isolation material, instead of a laminate, allows for a smaller critical separation between second primary winding 2007 and second secondary winding 2008 while maintaining the same voltage insulation and allows for improved thermal performance of isolation circuit 204.

Both transformers 228a and 228b can be formed in two metal layers. For example, as shown in FIG. 21 and FIG. 22, second primary winding 2007, center tap metal interconnects 2101, metal interconnects 2103, third primary winding 2010, center tap metal interconnects 2112, and metal interconnects 2111 can be formed on a first metal layer (e.g., the top metal layer). Second secondary winding 2008, center tap metal interconnects 2102, metal interconnects 2114, third secondary winding 2011, and center tap metal interconnects 2111 can be formed on a second metal layer below the first metal layer. The two-layer configuration is achieved by trading off coupling between primary and secondary windings to achieve a layout symmetry of the primary and secondary windings that result in lower parasitic barrier capacitance and less electromagnetic radiation. In some examples, with the two-layer configuration, the semiconductor die need not be placed over the transformer, which allows more flexible placement of metal pillars that provide electrical connection between the semiconductor die and the transformer, and relax the constraints on semiconductor the die size imposed by the placement of the metal pillars.

FIG. 23 is a schematic showing an isometric view of a packaged IC 2300 with partially overlapping primary and secondary windings of the data transformers, in accordance with at least one example. Here, packaged IC 2300 is similar to packaged IC 2200 in feature and functionality, with each center tap metal interconnect having a straight portion, and symmetry/matching is achieved by having the pair metal interconnects coupled between the primary/secondary side terminals and the data circuits to be of equal distance to the straight portion, as explained above. The arrangements in FIG. 23 allow the transformers to be more compact.

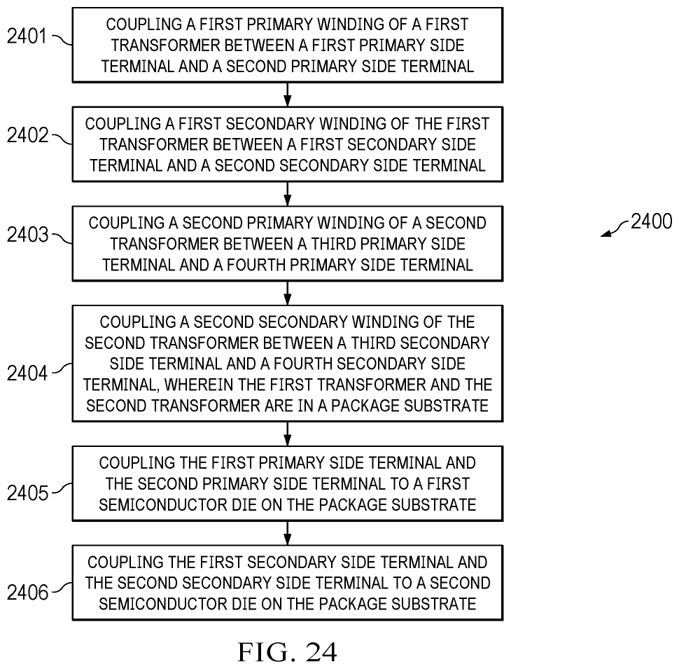

FIG. 24 is a flowchart 2400 of a method of forming the packaged integrated circuit with three transformers, in accordance with at least one example. Various blocks of flowchart 2400 are shown in a particular order. The order can be modified. For example, some blocks can be performed before others and some blocks may be performed in parallel. Flowchart 2400 may be implemented using routable lead frame technology and may be performed as part of a process for manufacturing packaged ICs, such as packaged ICs of FIGS. 15-23.

At block 2401, first primary winding 1503 of first transformer 206 is formed and coupled between first primary side terminal 1505a and second primary side terminal 1505b. At block 2402, first secondary winding 1504 of first transformer 206 is formed and coupled between a first secondary side terminal 1506a and a second secondary side terminal 1506b. At block 2403, second primary winding 1507 of second transformer 228a is formed and coupled between third primary side terminal 1331a and a fourth primary side terminal 1333a. At block 2404, second secondary winding 1508 of second transformer 228a is formed and coupled between third secondary side terminal 1334a and fourth secondary side terminal 1336a, wherein first transformer 206 and second transformer 228a are in package substrate 202. In some examples, package substrate 202 may have another semiconductor die (e.g., semiconductor die 242) mounted thereon prior to forming of first transformer 206 and/or second transformer 228a. In some examples, another semiconductor die (e.g., semiconductor die 242) can be electrically coupled to package substrate 202 via bond wires.

At block 2405, first primary side terminal 1505a and the second primary side terminal 1505b are coupled to first semiconductor die 211 on package substrate 202. At block 2406, first secondary side terminal 1506a and second secondary side terminal 1506b are coupled to second semiconductor die 220 on package substrate 202.

In at least one example, the method of flowchart 2400 includes overlapping first semiconductor die 211 over a part of first primary winding 1503 and first secondary winding 1504. In at least one example, first semiconductor die 211 is coupled to first primary side terminal 1505a and second primary side terminal 1505b via first metal pillars (e.g., copper pillars). In at least one example, second semiconductor die 220 is coupled to first secondary side terminal 1506a and second secondary side terminal 1506b via second metal pillars.

The following are additional examples provided in view of the above-described implementations. Here, one or more features of example, in isolation or in combination, can be combined with one or more features of one or more other examples to form further examples also falling within the scope of the disclosure. As such, one implementation can be combined with one or more other implementation without changing the scope of disclosure.

Example 1 is a packaged integrated circuit comprising: a package substrate including an isolation circuit, the isolation circuit including a first primary side terminal, a second primary side terminal, a first secondary side terminal, and a second secondary side terminal; a first semiconductor die on the package substrate and coupled to the first primary side terminal and the second primary side terminal; and a second semiconductor die on the package substrate and coupled to the first secondary side terminal and the second secondary side terminal.

Example 2 is packaged integrated circuit according to any example herein, in particular example 1, wherein the package substrate includes one or more transformers including a first transformer, the first transformer including a first primary winding and a first secondary winding, the first primary winding coupled between the first primary side terminal and the second primary side terminal, and the first secondary winding coupled between the first secondary side terminal and the second secondary side terminal.

Example 3 is packaged integrated circuit according to any example herein, in particular example 2, wherein the package substrate includes a first metal layer and a second metal layer below the first metal layer, and wherein the first primary winding is in the first metal layer, and the first secondary winding is in the second metal layer.

Example 4 is packaged integrated circuit according to any example herein, in particular example 3, further comprising a first metal interconnect and a second metal interconnect in the first metal layer, and a third metal interconnect and a fourth metal interconnect in the second metal layer, wherein: the first metal interconnect is coupled between the first primary side terminal of the first primary winding and the first semiconductor die; the third metal interconnect is coupled between the second primary side terminal of the first primary winding and the first semiconductor die; the second metal interconnect is coupled between the first secondary side terminal of the first secondary winding and the second semiconductor die; and the fourth metal interconnect is coupled between the second secondary side terminal of the first secondary winding and the second semiconductor die.

Example 5 is packaged integrated circuit according to any example herein, in particular example 4, further comprising a first metal pillar coupled between the first metal interconnect and the first semiconductor die, a second metal pillar coupled between the third metal interconnect and the first semiconductor die, a third metal pillar coupled between the second metal interconnect and the second semiconductor die, and a fourth metal pillar coupled between the fourth metal interconnect and the second semiconductor die.

Example 6 is packaged integrated circuit according to any example herein, in particular example 3, further comprising a first metal interconnect, a second metal interconnect, and a third metal interconnect in the first metal layer and a fourth metal interconnect in the second metal layer, wherein: the first metal interconnect is coupled between the first primary side terminal of the first primary winding and the first semiconductor die; the second metal interconnect is coupled between the second primary side terminal of the first primary winding and the first semiconductor die; the third metal interconnect is coupled between the first secondary side terminal of the first secondary winding and the second semiconductor die; and the fourth metal interconnect is coupled between the second secondary side terminal of the first secondary winding and the second semiconductor die.

Example 7 is packaged integrated circuit according to any example herein, in particular example 6, further comprising a first bond wire coupled between second interconnect and the second primary side terminal of the first primary winding, and a second bond wire coupled between the first secondary side terminal of the first secondary winding and the third metal interconnect.

Example 8 is packaged integrated circuit according to any example herein, in particular example 6, further comprising a first metal pillar coupled between the first metal interconnect and the first semiconductor die, a second metal pillar coupled between the second metal interconnect and the first semiconductor die, a third metal pillar coupled between the third metal interconnect and the second semiconductor die, and a fourth metal pillar coupled between the fourth metal interconnect and the second semiconductor die.

Example 9 is packaged integrated circuit according to any example herein, in particular example 2, wherein the package substrate includes a first metal layer, a second metal layer, and a third metal layer, the second metal layer being between the first and third metal layers; wherein the first primary winding is in the first metal layer, and the first secondary winding is in the second metal layer; wherein the first semiconductor die is coupled to the first primary winding; and wherein the package substrate includes a first metal interconnect and a second metal interconnect in the third metal layer, the first metal interconnect coupled between a first secondary side terminal of the first secondary winding and the second semiconductor die, and the second metal interconnect coupled between the second primary side terminal of the first secondary winding and the second semiconductor die.

Example 10 is packaged integrated circuit according to any example herein, in particular example 2, wherein the isolation circuit includes a third primary side terminal, a fourth primary side terminal, a third secondary side terminal, and a fourth secondary side terminal.

Example 11 is packaged integrated circuit according to any example herein, in particular example 10, wherein the isolation circuit includes a first capacitor and a second capacitor, the first capacitor coupled between the third primary side terminal and the third secondary side terminal, and the second capacitor coupled between the fourth primary side terminal and the fourth secondary side terminal.

Example 12 is packaged integrated circuit according to any example herein, in particular example 10, wherein the one or more transformers include a second transformer including a second primary winding and a second secondary winding, the second primary winding coupled between the third primary side terminal and the fourth primary side terminal, and the second secondary winding coupled between the third secondary side terminal and the fourth secondary side terminal.

Example 13 is packaged integrated circuit according to any example herein, in particular example 12, wherein the second transformer is outside a footprint of the first transformer.

Example 14 is packaged integrated circuit according to any example herein, in particular example 13, further comprising a third semiconductor die and a fourth semiconductor die, the third semiconductor die coupled to the third primary side terminal and the fourth primary side terminal, and the fourth semiconductor die coupled to the third secondary side terminal and the fourth secondary side terminal.

Example 15 is packaged integrated circuit according to any example herein, in particular example 12, wherein the second transformer is within a footprint of the first transformer.

Example 16 is packaged integrated circuit according to any example herein, in particular example 15, wherein the first semiconductor die is coupled to the third primary side terminal and the fourth primary side terminal, and the second semiconductor die is coupled to the third secondary side terminal and the fourth secondary side terminal.

Example 17 is packaged integrated circuit according to any example herein, in particular example 12, wherein the second primary winding includes a first coil portion and a second coil portion coupled to a first center tap; and wherein the second secondary winding includes a third coil portion and a fourth coil portion coupled to a second center tap.

Example 18 is packaged integrated circuit according to any example herein, in particular example 17, wherein: the first and second center taps are within a footprint of the second transformer; the package substrate includes a first metal layer, a second metal layer, and a third metal layer, the second metal layer being between the first and third metal layers; the second primary winding is in the first metal layer and is coupled to one of the first semiconductor die or a third semiconductor die that overlaps with the second primary winding; the second secondary winding is in the second metal layer; and the third metal layer includes metal interconnects coupled between the second secondary winding and one of the second semiconductor die or a fourth semiconductor die.

Example 19 is packaged integrated circuit according to any example herein, in particular example 17, wherein: the first and second center taps are outside a footprint of the second transformer; the package substrate includes a first metal layer and a second metal layer; the first metal layer includes the second primary winding, a first metal interconnect coupled between the first center tap and the second primary winding, and a pair of second metal interconnects coupled between the second secondary winding and one of the second semiconductor die or a third semiconductor die on a periphery of the second transformer; and the second metal layer includes the second secondary winding, a third metal interconnect coupled between the second center tap and the second secondary winding, and a pair of fourth metal interconnects coupled between the second primary winding and one of the first semiconductor die or a fourth semiconductor die on a periphery of the second transformer.

Example 20 is packaged integrated circuit according to any example herein, in particular example 19, wherein the first metal interconnect includes a first branch portion that overlaps with the pair of fourth metal interconnects; and wherein the third metal interconnect includes a second branch portion that overlaps with the pair of second metal interconnects.

Example 21 is packaged integrated circuit according to any example herein, in particular example 19, wherein the first metal interconnect includes a first straight portion that is of equal distance to each one of the pair of fourth metal interconnects; and wherein the third metal interconnect includes a second straight portion that is of equal distance to each one of the pair of second metal interconnects.

Example 22 is packaged integrated circuit according to any example herein, in particular example 21, wherein the isolation circuit includes a fifth primary side terminal, a sixth primary side terminal, a fifth secondary side terminal, and a sixth secondary side terminal; and wherein the one or more transformers include a third transformer including a third primary winding and a third secondary winding, the third primary winding coupled between the fifth primary side terminal and the sixth primary side terminal, and the third secondary winding coupled between the fifth secondary side terminal and the sixth secondary side terminal.

Example 23 is packaged integrated circuit according to any example herein, in particular example 22, wherein the third transformer is outside a footprint of the first transformer.

Example 24 is packaged integrated circuit according to any example herein, in particular example 22, wherein the third transformer is inside a footprint of the first transformer.

Example 25 is packaged integrated circuit according to any example herein, in particular example 12, further comprising a third semiconductor die and a fourth semiconductor die, the third semiconductor die coupled to the third primary side terminal and the fourth primary side terminal, and the fourth semiconductor die coupled to the third secondary side terminal and the fourth secondary side terminal.

Example 26 is packaged integrated circuit according to any example herein, in particular example 1, wherein the first primary side terminal, the second primary side terminal, the first secondary side terminal, and the second secondary side terminal are on a first surface of the package substrate, the first and second semiconductor dies being mounted on the first surface; wherein the package substrate further includes first and second metal pads on a second surface of the package substrate opposing the first surface, the first semiconductor die coupled to at least some of the first metal pads, and the second semiconductor die coupled to at least some of the second metal pads.

Example 27 is packaged integrated circuit according to any example herein, in particular example 26, wherein the first metal pads are on a first side of the package substrate, the second metal pads are on a second side of the package substrate opposing the first side, and a first number of the first metal pads being different from a second number of the second metal pads.

Example 28 is packaged integrated circuit according to any example herein, in particular example 1, wherein the package substrate is part of a routable lead frame.

Example 29 is packaged integrated circuit comprising: a package substrate including: a first transformer including a first primary winding and a first secondary winding, the first primary winding coupled between a first primary side terminal and a second primary side terminal, and the first secondary winding coupled between a first secondary side terminal and a second secondary side terminal; and a second transformer including a second primary winding and a second secondary winding, the second primary winding coupled between a third primary side terminal and a fourth primary side terminal, and the second secondary winding coupled between a third secondary side terminal and a fourth secondary side terminal; a first semiconductor die on the package substrate and coupled to the first primary side terminal and the second primary side terminal; a second semiconductor die on the package substrate and coupled to the first secondary side terminal and the second secondary side terminal; a first data circuit on the package substrate and coupled to the third primary side terminal and the fourth primary side terminal; and a second data circuit on the package substrate and coupled to the third secondary side terminal and the fourth secondary side terminal.

Example 30 is packaged integrated circuit according to any example herein, in particular example 29, wherein the first semiconductor die is coupled to the first primary side terminal and the second primary side terminal via first metal pillars, and the second semiconductor die is coupled to the first secondary side terminal and the second secondary side terminal via second metal pillars.

Example 31 is packaged integrated circuit according to any example herein, in particular example 29, wherein the first semiconductor die overlaps part of the first primary winding and the first secondary winding.

Example 32 is packaged integrated circuit according to any example herein, in particular example 29, wherein the package substrate includes a first metal layer, a second metal layer, and a third metal layer, the second metal layer being between the first and third metal layers; wherein the first primary winding is in the first metal layer, and the first secondary winding is in the second metal layer; wherein the first semiconductor die is coupled to the first primary winding; and wherein the package substrate includes a first metal interconnect and a second metal interconnect in the third metal layer, the first metal interconnect coupled between a first end of the first secondary winding and the second semiconductor die, and the second metal interconnect coupled between a second end of the first secondary winding and the second semiconductor die.

Example 33 is packaged integrated circuit according to any example herein, in particular example 29, wherein the second transformer is outside a footprint of the first transformer.

Example 34 is packaged integrated circuit according to any example herein, in particular example 33, further comprising a third semiconductor die including the first data circuit and a fourth semiconductor die including the second data circuit, the third semiconductor die coupled to the third primary side terminal and the fourth primary side terminal, and the fourth semiconductor die coupled to the third secondary side terminal and the fourth secondary side terminal.

Example 35 is packaged integrated circuit according to any example herein, in particular example 34, wherein each of the first and second semiconductor dies includes a respective half bridge circuit or a respective full bridge circuit, and each of the third and fourth semiconductor dies includes a respective data transmit circuit and a respective data receive circuit.

Example 36 is packaged integrated circuit according to any example herein, in particular example 34, further comprising a fifth semiconductor die having power terminals and data terminals, the power terminals coupled to the second semiconductor die, and the data terminals coupled to the fourth semiconductor die.

Example 37 is packaged integrated circuit according to any example herein, in particular example 29, wherein the second transformer is within a footprint of the first transformer.

Example 38 is packaged integrated circuit according to any example herein, in particular example 37, wherein the first semiconductor die includes the first data circuit and is coupled to the third primary side terminal and the fourth primary side terminal, and the second semiconductor die includes the second data circuit and is coupled to the third secondary side terminal and the fourth secondary side terminal.

Example 39 is packaged integrated circuit according to any example herein, in particular example 38, wherein the first semiconductor die and the second semiconductor die, the first transformer, and the second transformer are part of an isolated power converter.

Example 40 is packaged integrated circuit according to any example herein, in particular example 29, wherein the second primary winding includes a first coil portion and a second coil portion coupled to a first center tap; and wherein the second secondary winding includes a third coil portion and a fourth coil portion coupled to a second center tap.

Example 41 is packaged integrated circuit according to any example herein, in particular example 40, wherein: the first and second center taps are within a footprint of the second transformer; the package substrate includes a first metal layer, a second metal layer, and a third metal layer, the second metal layer being between the first and third metal layers; the second primary winding is in the first metal layer and is coupled to one of the first semiconductor die or a third semiconductor die that overlaps with the second primary winding; the second secondary winding is in the second metal layer; and the third metal layer includes metal interconnects coupled between the second secondary winding and one of the second semiconductor die or a fourth semiconductor die.

Example 42 is packaged integrated circuit according to any example herein, in particular example 40, wherein: the first and second center taps are outside a footprint of the second transformer; the package substrate includes a first metal layer and a second metal layer; the first metal layer includes the second primary winding, a first metal interconnect coupled between the first center tap and the second primary winding, and a pair of second metal interconnects coupled between the second secondary winding and one of the second semiconductor die or a third semiconductor die on a periphery of the second transformer; and the second metal layer includes the second secondary winding, a third metal interconnect coupled between the second center tap and the second primary winding, and a pair of fourth metal interconnects coupled between the second primary winding and one of the first semiconductor die or a fourth semiconductor die on a periphery of the second transformer.

Example 43 is packaged integrated circuit according to any example herein, in particular example 42, wherein the first metal interconnect includes a first branch portion that overlaps with the pair of fourth metal interconnects; and wherein the third metal interconnect includes a second branch portion that overlaps with the pair of second metal interconnects.

Example 44 is packaged integrated circuit according to any example herein, in particular example 42, wherein the first metal interconnect includes a first straight portion that is of equal distance to each one of the pair of fourth metal interconnects; and wherein the third metal interconnect includes a second straight portion that is of equal distance to each one of the pair of second metal interconnects.

Example 45 is packaged integrated circuit according to any example herein, in particular example 29, wherein the first primary side terminal, the second primary side terminal, the first secondary side terminal, and the second secondary side terminal are on a first surface of the package substrate, the first and second semiconductor dies being mounted on the first surface; and wherein the package substrate further includes first and second metal pads on a second surface of the package substrate opposing the first surface, the first semiconductor die coupled to at least some of the first metal pads, and the second semiconductor die coupled to at least some of the second metal pads.

Example 46 is packaged integrated circuit according to any example herein, in particular example 45, wherein the first metal pads are on a first side of the package substrate, the second metal pads are on a second side of the package substrate opposing the first side, and a first number of the first metal pads being different from a second number of the second metal pads.

Example 47 is packaged integrated circuit according to any example herein, in particular example 29, wherein the package substrate is part of a routable lead frame.

Example 48 is packaged integrated circuit according to any example herein, in particular example 29, wherein the first semiconductor die and the second semiconductor die are flip-chip dies.

Example 49 is a method comprising: coupling a first primary winding of a first transformer between a first primary side terminal and a second primary side terminal; coupling a first secondary winding of the first transformer between a first secondary side terminal and a second secondary side terminal; coupling a second primary winding of a second transformer between a third primary side terminal and a fourth primary side terminal; coupling a second secondary winding of the second transformer between a third secondary side terminal and a fourth secondary side terminal, wherein the first transformer and the second transformer are in a package substrate; coupling the first primary side terminal and the second primary side terminal to a first semiconductor die on the package substrate; and coupling the first secondary side terminal and the second secondary side terminal to a second semiconductor die on the package substrate.

Example 50 is a method according to any example herein, in particular example 49 wherein the first semiconductor die is coupled to the first primary side terminal and the second primary side terminal via first metal pillars, and the second semiconductor die is coupled to the first secondary side terminal and the second secondary side terminal via second metal pillars.

Example 51 is a packaged integrated circuit according to any example herein, in particular example 49, which further includes overlapping the first semiconductor die over a part of the first primary winding and the first secondary winding.

Besides what is described herein, various modifications can be made to disclose implementations and implementations thereof without departing from their scope. Therefore, illustrations of implementations herein should be construed as examples, and not restrictive to scope of present disclosure.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In the description and in the claims, the terms “including” and “having” and variants thereof are intended to be inclusive in a manner similar to the term “comprising” unless otherwise noted. In addition, the terms “couple”, “coupled” or “couples” means an indirect or direct electrical or mechanical connection.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuit or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuit. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN) or a gallium arsenide substrate (GaAs).

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

What is claimed is:

1. A packaged integrated circuit comprising:
a package substrate including an isolation circuit, the isolation circuit including a first primary side terminal, a second primary side terminal, a first secondary side terminal, and a second secondary side terminal;
a first semiconductor die on the package substrate and coupled to the first primary side terminal and the second primary side terminal; and
a second semiconductor die on the package substrate and coupled to the first secondary side terminal and the second secondary side terminal.

2. The packaged integrated circuit of claim 1, wherein the package substrate includes one or more transformers including a first transformer, the first transformer including a first primary winding and a first secondary winding, the first primary winding coupled between the first primary side terminal and the second primary side terminal, and the first secondary winding coupled between the first secondary side terminal and the second secondary side terminal.

3. The packaged integrated circuit of claim 2, wherein the package substrate includes a first metal layer and a second metal layer below the first metal layer, and wherein the first primary winding is in the first metal layer, and the first secondary winding is in the second metal layer.

4. The packaged integrated circuit of claim 3, further comprising a first metal interconnect and a second metal interconnect in the first metal layer, and a third metal interconnect and a fourth metal interconnect in the second metal layer, wherein:
the first metal interconnect is coupled between the first primary side terminal of the first primary winding and the first semiconductor die;
the third metal interconnect is coupled between the second primary side terminal of the first primary winding and the first semiconductor die;
the second metal interconnect is coupled between the first secondary side terminal of the first secondary winding and the second semiconductor die; and
the fourth metal interconnect is coupled between the second secondary side terminal of the first secondary winding and the second semiconductor die.

5. The packaged integrated circuit of claim 4, further comprising a first metal pillar coupled between the first metal interconnect and the first semiconductor die, a second metal pillar coupled between the third metal interconnect and the first semiconductor die, a third metal pillar coupled between the second metal interconnect and the second semiconductor die, and a fourth metal pillar coupled between the fourth metal interconnect and the second semiconductor die.

6. The packaged integrated circuit of claim 3, further comprising a first metal interconnect, a second metal interconnect, and a third metal interconnect in the first metal layer and a fourth metal interconnect in the second metal layer, wherein:
the first metal interconnect is coupled between the first primary side terminal of the first primary winding and the first semiconductor die;
the second metal interconnect is coupled between the second primary side terminal of the first primary winding and the first semiconductor die;
the third metal interconnect is coupled between the first secondary side terminal of the first secondary winding and the second semiconductor die; and
the fourth metal interconnect is coupled between the second secondary side terminal of the first secondary winding and the second semiconductor die.

7. The packaged integrated circuit of claim 6, further comprising a first bond wire coupled between second interconnect and the second primary side terminal of the first primary winding, and a second bond wire coupled between the first secondary side terminal of the first secondary winding and the third metal interconnect.

8. The packaged integrated circuit of claim 6, further comprising a first metal pillar coupled between the first metal interconnect and the first semiconductor die, a second metal pillar coupled between the second metal interconnect and the first semiconductor die, a third metal pillar coupled between the third metal interconnect and the second semiconductor die, and a fourth metal pillar coupled between the fourth metal interconnect and the second semiconductor die.

9. The packaged integrated circuit of claim 2, wherein the package substrate includes a first metal layer, a second metal layer, and a third metal layer, the second metal layer being between the first and third metal layers;
wherein the first primary winding is in the first metal layer, and the first secondary winding is in the second metal layer;
wherein the first semiconductor die is coupled to the first primary winding; and
wherein the package substrate includes a first metal interconnect and a second metal interconnect in the third metal layer, the first metal interconnect coupled between a first secondary side terminal of the first secondary winding and the second semiconductor die, and the second metal interconnect coupled between the second primary side terminal of the first secondary winding and the second semiconductor die.

10. The packaged integrated circuit of claim 2, wherein the isolation circuit includes a third primary side terminal, a fourth primary side terminal, a third secondary side terminal, and a fourth secondary side terminal.

11. The packaged integrated circuit of claim 10, wherein the isolation circuit includes a first capacitor and a second capacitor, the first capacitor coupled between the third primary side terminal and the third secondary side terminal, and the second capacitor coupled between the fourth primary side terminal and the fourth secondary side terminal.

12. The packaged integrated circuit of claim 10, wherein the one or more transformers include a second transformer including a second primary winding and a second secondary winding, the second primary winding coupled between the third primary side terminal and the fourth primary side terminal, and the second secondary winding coupled between the third secondary side terminal and the fourth secondary side terminal.

13. The packaged integrated circuit of claim 12, wherein the second transformer is outside a footprint of the first transformer.

14. The packaged integrated circuit of claim 13, further comprising a third semiconductor die and a fourth semiconductor die, the third semiconductor die coupled to the third primary side terminal and the fourth primary side terminal, and the fourth semiconductor die coupled to the third secondary side terminal and the fourth secondary side terminal.

15. The packaged integrated circuit of claim 12, wherein the second transformer is within a footprint of the first transformer.

16. The packaged integrated circuit of claim 15, wherein the first semiconductor die is coupled to the third primary side terminal and the fourth primary side terminal, and the second semiconductor die is coupled to the third secondary side terminal and the fourth secondary side terminal.

17. The packaged integrated circuit of claim 12, wherein the second primary winding includes a first coil portion and a second coil portion coupled to a first center tap; and
wherein the second secondary winding includes a third coil portion and a fourth coil portion coupled to a second center tap.

18. The packaged integrated circuit of claim 17, wherein:
the first and second center taps are within a footprint of the second transformer;
the package substrate includes a first metal layer, a second metal layer, and a third metal layer, the second metal layer being between the first and third metal layers;
the second primary winding is in the first metal layer and is coupled to one of the first semiconductor die or a third semiconductor die that overlaps with the second primary winding;
the second secondary winding is in the second metal layer; and
the third metal layer includes metal interconnects coupled between the second secondary winding and one of the second semiconductor die or a fourth semiconductor die.

19. The packaged integrated circuit of claim 17, wherein:
the first and second center taps are outside a footprint of the second transformer;
the package substrate includes a first metal layer and a second metal layer;
the first metal layer includes the second primary winding, a first metal interconnect coupled between the first center tap and the second primary winding, and a pair of second metal interconnects coupled between the second secondary winding and one of the second semiconductor die or a third semiconductor die on a periphery of the second transformer; and
the second metal layer includes the second secondary winding, a third metal interconnect coupled between the second center tap and the second secondary winding, and a pair of fourth metal interconnects coupled between the second primary winding and one of the first semiconductor die or a fourth semiconductor die on a periphery of the second transformer.

20. The packaged integrated circuit of claim 19, wherein the first metal interconnect includes a first branch portion that overlaps with the pair of fourth metal interconnects; and
wherein the third metal interconnect includes a second branch portion that overlaps with the pair of second metal interconnects.

21. The packaged integrated circuit of claim 19, wherein the first metal interconnect includes a first straight portion that is of equal distance to each one of the pair of fourth metal interconnects; and
wherein the third metal interconnect includes a second straight portion that is of equal distance to each one of the pair of second metal interconnects.

22. The packaged integrated circuit of claim 21, wherein the isolation circuit includes a fifth primary side terminal, a sixth primary side terminal, a fifth secondary side terminal, and a sixth secondary side terminal; and
wherein the one or more transformers include a third transformer including a third primary winding and a third secondary winding, the third primary winding coupled between the fifth primary side terminal and the sixth primary side terminal, and the third secondary winding coupled between the fifth secondary side terminal and the sixth secondary side terminal.

23. The packaged integrated circuit of claim 22, wherein the third transformer is outside a footprint of the first transformer.

24. The packaged integrated circuit of claim 22, wherein the third transformer is inside a footprint of the first transformer.

25. The packaged integrated circuit of claim 12, further comprising a third semiconductor die and a fourth semiconductor die, the third semiconductor die coupled to the third primary side terminal and the fourth primary side terminal, and the fourth semiconductor die coupled to the third secondary side terminal and the fourth secondary side terminal.

26. The packaged integrated circuit of claim 1, wherein the first primary side terminal, the second primary side terminal, the first secondary side terminal, and the second secondary side terminal are on a first surface of the package substrate, the first and second semiconductor dies being mounted on the first surface;
wherein the package substrate further includes first and second metal pads on a second surface of the package substrate opposing the first surface, the first semiconductor die coupled to at least some of the first metal pads, and the second semiconductor die coupled to at least some of the second metal pads.

27. The packaged integrated circuit of claim 26, wherein the first metal pads are on a first side of the package substrate, the second metal pads are on a second side of the package substrate opposing the first side, and a first number of the first metal pads being different from a second number of the second metal pads.

28. The packaged integrated circuit of claim 1, wherein the package substrate is part of a routable lead frame.

29. A packaged integrated circuit comprising:
a package substrate including:
a first transformer including a first primary winding and a first secondary winding, the first primary winding coupled between a first primary side terminal and a second primary side terminal, and the first secondary winding coupled between a first secondary side terminal and a second secondary side terminal; and
a second transformer including a second primary winding and a second secondary winding, the second primary winding coupled between a third primary side terminal and a fourth primary side terminal, and the second secondary winding coupled between a third secondary side terminal and a fourth secondary side terminal;
a first semiconductor die on the package substrate and coupled to the first primary side terminal and the second primary side terminal;
a second semiconductor die on the package substrate and coupled to the first secondary side terminal and the second secondary side terminal;
a first data circuit on the package substrate and coupled to the third primary side terminal and the fourth primary side terminal; and
a second data circuit on the package substrate and coupled to the third secondary side terminal and the fourth secondary side terminal.

30. The packaged integrated circuit of claim 29, wherein the first semiconductor die is coupled to the first primary side terminal and the second primary side terminal via first metal pillars, and the second semiconductor die is coupled to the first secondary side terminal and the second secondary side terminal via second metal pillars.

31. The packaged integrated circuit of claim 29, wherein the first semiconductor die overlaps part of the first primary winding and the first secondary winding.

32. The packaged integrated circuit of claim 29, wherein the package substrate includes a first metal layer, a second metal layer, and a third metal layer, the second metal layer being between the first and third metal layers;
wherein the first primary winding is in the first metal layer, and the first secondary winding is in the second metal layer;
wherein the first semiconductor die is coupled to the first primary winding; and
wherein the package substrate includes a first metal interconnect and a second metal interconnect in the third metal layer, the first metal interconnect coupled between a first end of the first secondary winding and the second semiconductor die, and the second metal interconnect coupled between a second end of the first secondary winding and the second semiconductor die.

33. The packaged integrated circuit of claim 29, wherein the second transformer is outside a footprint of the first transformer.

34. The packaged integrated circuit of claim 33, further comprising a third semiconductor die including the first data circuit and a fourth semiconductor die including the second data circuit, the third semiconductor die coupled to the third primary side terminal and the fourth primary side terminal, and the fourth semiconductor die coupled to the third secondary side terminal and the fourth secondary side terminal.

35. The packaged integrated circuit of claim 34, wherein each of the first and second semiconductor dies includes a respective half bridge circuit or a full bridge circuit, and each of the third and fourth semiconductor dies includes a respective data transmit circuit and a respective data receive circuit.

36. The packaged integrated circuit of claim 34, further comprising a fifth semiconductor die having power terminals and data terminals, the power terminals coupled to the second semiconductor die, and the data terminals coupled to the fourth semiconductor die.

37. The packaged integrated circuit of claim 29, wherein the second transformer is within a footprint of the first transformer.

38. The packaged integrated circuit of claim 37, wherein the first semiconductor die includes the first data circuit and is coupled to the third primary side terminal and the fourth primary side terminal, and the second semiconductor die includes the second data circuit and is coupled to the third secondary side terminal and the fourth secondary side terminal.

39. The packaged integrated circuit of claim 38, wherein the first semiconductor die and the second semiconductor die, the first transformer, and the second transformer are part of an isolated power converter.

40. The packaged integrated circuit of claim 29, wherein the second primary winding includes a first coil portion and a second coil portion coupled to a first center tap; and
wherein the second secondary winding includes a third coil portion and a fourth coil portion coupled to a second center tap.

41. The packaged integrated circuit of claim 40, wherein:
the first and second center taps are within a footprint of the second transformer;
the package substrate includes a first metal layer, a second metal layer, and a third metal layer, the second metal layer being between the first and third metal layers;
the second primary winding is in the first metal layer and is coupled to one of the first semiconductor die or a third semiconductor die that overlaps with the second primary winding;
the second secondary winding is in the second metal layer; and
the third metal layer includes metal interconnects coupled between the second secondary winding and one of the second semiconductor die or a fourth semiconductor die.

42. The packaged integrated circuit of claim 40, wherein:
the first and second center taps are outside a footprint of the second transformer;
the package substrate includes a first metal layer and a second metal layer;
the first metal layer includes the second primary winding, a first metal interconnect coupled between the first center tap and the second primary winding, and a pair of second metal interconnects coupled between the second secondary winding and one of the second semiconductor die or a third semiconductor die on a periphery of the second transformer; and
the second metal layer includes the second secondary winding, a third metal interconnect coupled between the second center tap and the second primary winding, and a pair of fourth metal interconnects coupled between the second primary winding and one of the first semiconductor die or a fourth semiconductor die on a periphery of the second transformer.

43. The packaged integrated circuit of claim 42, wherein the first metal interconnect includes a first branch portion that overlaps with the pair of fourth metal interconnects; and
wherein the third metal interconnect includes a second branch portion that overlaps with the pair of second metal interconnects.

44. The packaged integrated circuit of claim 42, wherein the first metal interconnect includes a first straight portion that is of equal distance to each one of the pair of fourth metal interconnects; and
wherein the third metal interconnect includes a second straight portion that is of equal distance to each one of the pair of second metal interconnects.

45. The packaged integrated circuit of claim 29, wherein the first primary side terminal, the second primary side terminal, the first secondary side terminal, and the second secondary side terminal are on a first surface of the package substrate, the first and second semiconductor dies being mounted on the first surface; and
wherein the package substrate further includes first and second metal pads on a second surface of the package substrate opposing the first surface, the first semiconductor die coupled to at least some of the first metal pads, and the second semiconductor die coupled to at least some of the second metal pads.

46. The packaged integrated circuit of claim 45, wherein the first metal pads are on a first side of the package substrate, the second metal pads are on a second side of the package substrate opposing the first side, and a first number of the first metal pads being different from a second number of the second metal pads.

47. The packaged integrated circuit of claim 29, wherein the package substrate is part of a routable lead frame.

48. The packaged integrated circuit of claim 29, wherein the first semiconductor die and the second semiconductor die are flip-chip dies.
